(19) United States
(12) Patent Application Publication
(10) Pub. No.: US 2025/0218803 A1
(43) Pub. Date: Jul. 3, 2025

(54) TRANSFER CHAMBERS, ASSOCIATED SEMICONDUCTOR PROCESSING SYSTEMS, AND METHODS FOR PREVENTING MOISTURE ENTERING A TRANSFER CHAMBER

(71) Applicant: ASM IP Holding B.V., Almere (NL)

(72) Inventors: Coral Wang, Scottsdale, AZ (US); Salam Harb, Scottsdale, AZ (US); Samer Banna, Phoenix, AZ (US); Suzanne Wong, Tempe, AZ (US)

(21) Appl. No.: 18/990,164

(22) Filed: Dec. 20, 2024

Related U.S. Application Data
(60) Provisional application No. 63/615,111, filed on Dec. 27, 2023.

(51) Int. Cl. H01L 21/67; F16K 51/02

(52) U.S. Cl. CPC H01L 21/67017; F16K 51/02

(57) ABSTRACT

Transfer chambers, semiconductor processing systems including transfer chambers, and methods for preventing moisture from entering a transfer chamber are provided. The transfer chambers disclosed include one or more gas distributors for forming a gas curtain across openings in the transfer chamber thereby preventing moisture from entering the transfer chamber.

### CROSS-REFERENCE TO RELATED APPLICATION(S)

This Application claims the benefit of U.S. Provisional Application 63/615,111 filed on Dec. 27, 2023, the entire contents of which are incorporated herein by reference.

### FIELD

The present disclosure generally relates to the field of semiconductor processing apparatus, systems, and methods, and to the field of device and integrated circuit manufacture. More particularly, the present disclosure relates to transfer chambers configured for reducing moisture content, semiconductor processing systems including such transfer chambers, and associated methods for reducing moisture content in transfer chambers associated with semiconductor processing systems.

### BACKGROUND

Semiconductor processing systems commonly employ transfer chambers during the manufacturing of semiconductor devices and integrated circuits (ICs). For example, unprocessed substrates can be transported from cassettes into a transfer chamber, such as a load lock chamber. Substrates can then be transported from the transfer chamber to a process module for processing. Once a process is complete in one process module, the substrate can be transferred to a different process module to continue processing the substrate. During the transfer of substrate between different process modules the substrate can pass through one or more different transfer chambers multiple times. Once processing of the substrate is completed the substrate is typically moved back to a transfer chamber (e.g., the load lock chamber) for cooling, post-processing and transport (e.g., out of the semiconductor processing system).

Transfer chambers commonly employ gate valves to allow a substrate to controllably enter and exit the transfer chamber while maintaining the environment (e.g., the pressure and/or gas ambient) within the adjoining chambers of the semiconductor processing system connected to the transfer chamber. When the gate valve is open, to allow transfer of the substrate, there is a possibility of unwanted moisture entering the transfer chamber. However, moisture in the transfer chamber (and adjoining chambers) can have a negative impact on the substrates, the processes being performed in the process modules, and/or the semiconductor processing system itself. For example, moisture can introduce particulate contamination which can affect the quality of the substrate and any layers deposited thereon. As a further example, moisture can disrupt the vacuum conditions in the transfer chamber and adjoining vacuum chambers. In addition, the presence of moisture can increase the time needed to pump-down the transfer chamber and/or adjoining chambers to a reduced pressure, which can slow down the overall device/IC fabrication process and consequently the throughput of substrates through the semiconductor processing system. Further, transfer chambers commonly provide a clean and stable environment for handling delicate materials disposed on the substrate and moisture within such transfer chamber can potentially damage these materials.

There is thus a general desire for transfer chambers which are configured for reducing moisture content within the transfer chamber, as well as in the semiconductor processing systems including such transfer chambers, and associated methods for preventing moisture from entering transfer chambers.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to transfer chambers including apparatus for forming protective gas curtain, as well as associated semiconductor processing systems and methods.

In accordance with examples of the disclosure a transfer chamber is disclosed, the transfer chamber including a housing including a first opening through which a substrate is transferred into and out of a first passage within the housing. In such examples, the transfer chamber includes a first gate valve disposed on a front face of the housing, where the first gate valve is either set to an open position to allow the transfer of the substrate into the first passage through the first opening or is set to a closed position to form a vacuum seal over the first opening. In such examples one or more gas distributors disposed on the housing proximate to the first gate valve, the one or more gas distributors including a plurality of gas directing channels for directing an inert gas over the first opening of the housing to form a gas curtain over the first opening.

In some embodiments, the one or more gas distributors are disposed within the housing.

In some embodiments, the one or more gas distributors are disposed on an external face of the housing.

In some embodiments, the one or more gas distributors are positioned above and/or below the first opening and the gas directing channels extend in a vertical direction for directing the inert gas across a width of the first opening.

In some embodiments, the one or more gas distributors are positioned on a side of the first opening and the gas directing channels extend in a horizontal direction for directing the inert gas across a height of the first opening.

In some embodiments, the housing also includes a second opening disposed to a side of the first opening and a second gate valve disposed on the front face of the housing, where the second gate valve is either set to the open position to allow passage of the substrate into a second passage through the second opening or is set to the closed position to form a vacuum seal over the second opening.

In some embodiments, the one or more gas distributors are positioned above the first opening and the second opening and/or below the first opening and the second opening, and the gas directing channels extend in a vertical direction for directing the inert gas across a width of the first opening and a width of the second opening.

In some embodiments, the transfer chamber also includes a second gas distributor positioned above and/or below the second opening, the second gas distributor including second gas directing channels extending in a vertical direction for directing the inert gas across a width of the second opening.

In some embodiments, the one or more gas distributors are positioned between the first opening and the second opening and the gas distributors includes first horizontal gas directing channels and second horizontal gas directing channels, the first horizontal gas directing channels extending in a first horizontal direction for directing the inert gas across a height of the first opening and the second horizontal gas directing channels extending in a second horizontal direction for directing the inert gas across a height of the second opening, wherein the first horizontal gas directing channels and the second horizontal gas directing channels are constructed and arranged for directing the inert gas in opposing directions.

In some embodiments, the housing of transfer chamber also includes a third opening disposed below the first opening and a third gate valve disposed on the front face of the housing, where the third gate valve is either set to the open position to allow the transfer of the substrate into a third passage through the third opening or is set the closed position to form a vacuum seal over the third opening, and a fourth opening disposed below the second opening and to a side of the third opening, and a fourth gate valve disposed on the front face of the housing, where the fourth gate valve is either set to the open position to allow passage of the substrate into a fourth passage through the fourth opening or is set the closed position to form a vacuum seal over the fourth opening.

In some embodiments, the one or more gas distributors are positioned to a side of the first opening and the third opening and the gas directing channels extend in a horizontal direction for directing the inert gas across a height of the first opening and a height of the third opening.

In some embodiments, the transfer chamber also includes a third gas distributor positioned to a side of the third opening, the third gas distributor including third gas directing channels extending in a horizontal direction for directing the inert gas across a height of the third opening.

In some embodiments, the one or more gas distributors are positioned between the first opening and the third opening and the gas distributors includes first vertical gas directing channels and second vertical gas directing channels, the first vertical gas directing channels extending in a vertical direction for directing the inert gas across a width of the first opening and the second vertical gas directing channels extending in a vertical direction for directing the inert gas across a width of the third opening, wherein the first vertical gas directing channel and the second vertical gas directing channels are constructed and arranged for directing the inert gas in opposing directions.

In some embodiments, the one or more gas distributors are disposed to a side of the first opening and the third opening and/or to a side of the second opening and the fourth opening.

In some embodiments, one or more additional gas distributors are disposed above the first opening and the second opening, and/or below the first opening and the second opening, and/or below the third opening and the fourth opening.

In some embodiments, the transfer chamber also includes a gas diffuser disposed within the first passage of the housing, the gas diffuser configured distributing a second inert gas into the first passage of the housing.

In accordance with examples of the disclosure a semiconductor processing system is also disclosed, the semiconductor processing system including one or more embodiments of the transfer chamber of the present disclosure. In accordance with examples of the disclosure the semiconductor processing system includes a transfer chamber, and an equipment front-end module (EFEM) connected to a front face of a housing of the transfer chamber, the equipment front-end module housing a front-end substrate transfer robot. In such examples, the semiconductor processing system also includes a back-end transfer module (BETM) connected to a rear face of the housing of the transfer chamber, the back-end transfer module coupling a process module to the transfer chamber, and a controller configured to initiate a flow of an inert gas into one or more gas distributors disposed on the front face of the transfer chamber prior to transferring a substrate into the transfer chamber thereby forming a gas curtain between the transfer chamber and the equipment front-end module.

In some embodiments, the semiconductor processing system also includes an additional back-end transfer module including one or more additional process modules, and an additional transfer chamber, the additional transfer chamber coupling the additional back-end transfer module to the equipment front-end module.

In accordance with examples of the disclosure a method for preventing moisture from entering a transfer chamber is disclosed. In accordance with examples of the disclosure, the method includes flowing an inert gas into one or more gas distributors disposed on a housing of the transfer chamber. In such examples, the one or more gas distributors are positioned proximate to a first gate valve, and the one or more gas distributors include a plurality of gas directing channels for directing the inert gas over a first opening of the housing to form a gas curtain over the first opening. In such examples the method also includes opening the first gate valve disposed on a front face of the housing of the transfer chamber, and transferring a substrate into a first passage within the transfer chamber and seating the substrate on a substrate support disposed within the first passage. In such examples, the method also includes closing the first gate valve disposed on the front face of the housing of the transfer chamber, and stopping the flow of the inert gas into the one or more gas distributors disposed on the housing of the transfer chamber thereby shutting off the gas curtain. In some embodiments, the method also includes flowing a second inert gas into a gas diffuser disposed within the housing of the transfer chamber prior to opening the first gate valve.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary semiconductor processing system in accordance with one or more embodiments of the disclosure.

FIG. 2 illustrates a first view of an exemplary transfer chamber prior to the addition of components for preventing moisture entry into the transfer chamber.

FIG. 3 illustrates a second view of an exemplary transfer chamber prior to the addition of components for preventing moisture entry into the transfer chamber.

FIG. 4 illustrates a third view of an exemplary transfer chamber prior to the addition of components for preventing moisture entry into the transfer chamber.

FIG. 5 illustrates a first view of an exemplary transfer chamber including a first opening and one or more gas distributors in accordance with one or more embodiments of the disclosure.

FIG. 6 illustrates a second view of an exemplary transfer chamber including a first opening and one or more gas distributors in accordance with one or more embodiments of the disclosure.

FIG. 7 illustrates a first view of an additional exemplary transfer chamber including a first opening and one or more gas distributors in accordance with one or more embodiments of the disclosure.

FIG. 8 illustrates a second view of an additional exemplary transfer chamber including a first opening and one or more gas distributors in accordance with one or more embodiments of the disclosure.

FIG. 9 illustrates a first view of an exemplary transfer chamber including a first opening, a second opening and one or more gas distributors in accordance with one or more embodiments of the disclosure.

FIG. 10 illustrates a second view of an exemplary transfer chamber including a first opening, a second opening and one or more gas distributors in accordance with one or more embodiments of the disclosure.

FIG. 11 illustrates a first view of an additional exemplary transfer chamber including a first opening, a second opening and one or more gas distributors in accordance with one or more embodiments of the disclosure.

FIG. 12 illustrates a second view of an additional exemplary transfer chamber including a first opening, a second opening and one or more gas distributors in accordance with one or more embodiments of the disclosure.

FIG. 13 illustrates a first view of a further exemplary transfer chamber including a first opening, a second opening and one or more gas distributors in accordance with one or more embodiments of the disclosure.

FIG. 14 illustrates a second view of a further exemplary transfer chamber including a first opening, a second opening and one or more gas distributors in accordance with one or more embodiments of the disclosure.

FIG. 15 illustrates a first view an exemplary transfer chamber including a first opening, a third opening, and one or more gas distributors in accordance with one or more embodiments of the disclosure.

FIG. 16 illustrates a second view an exemplary transfer chamber including a first opening, a third opening, and one or more gas distributors in accordance with one or more embodiments of the disclosure.

FIG. 17 illustrates a first view an additional exemplary transfer chamber including a first opening, a third opening, and one or more gas distributors in accordance with one or more embodiments of the disclosure.

FIG. 18 illustrates a second view an additional exemplary transfer chamber including a first opening, a third opening, and one or more gas distributors in accordance with one or more embodiments of the disclosure.

FIG. 19 illustrates a first view a further exemplary transfer chamber including a first opening, a third opening, and one or more gas distributors in accordance with one or more embodiments of the disclosure.

FIG. 20 illustrates a second view a further exemplary transfer chamber including a first opening, a third opening, and one or more gas distributors in accordance with one or more embodiments of the disclosure.

FIG. 21 illustrates an exemplary transfer chamber including a first opening, a second opening, a third opening, a fourth opening, and one or more gas distributors in accordance with one or more embodiments of the disclosure.

FIG. 22 illustrates an additional exemplary transfer chamber including a first opening, a second opening, a third opening, a fourth opening, and one or more gas distributors in accordance with one or more embodiments of the disclosure.

FIG. 23 illustrates a further exemplary transfer chamber including a first opening, a second opening, a third opening, a fourth opening, and two or more gas distributors in accordance with one or more embodiments of the disclosure.

FIG. 24 illustrates a first view of an exemplary transfer chamber including a gas diffuser in accordance with one or more embodiments of the disclosure.

FIG. 25 illustrates a second view of an exemplary transfer chamber including a gas diffuser in accordance with one or more embodiments of the disclosure.

FIG. 26 illustrates a semiconductor processing system in accordance with one or more embodiments of the disclosure.

FIG. 27 illustrates an exemplary method for preventing moisture from entering a transfer chamber in accordance with one or more embodiments of the disclosure.

FIG. 28 illustrates a view of a portion of a semiconductor processing system in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “transfer chamber” can refer to any chamber arrangement which is configured for the handling, transferring, and/or storage of substrates prior to and/or post processing in a process module (or reactor, reaction chamber, and the like).

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

Various embodiments of the present disclosure relate to transfer chambers configured for reducing moisture content, as well as semiconductor processing system employing such transfer chambers, and associated methods for reducing moisture content in a semiconductor processing system. In some embodiments of the present disclosure, a transfer chamber includes one or more gas distributors configured for forming a protective gas curtain over the transfer chambers openings when transferring substrate into the transfer chamber. In some embodiments of the present disclosure, a transfer chamber includes one or more gas diffusers configured for over pressurizing the transfer chamber such that moisture is prevented from entering the transfer chamber during substrate transfer operations.

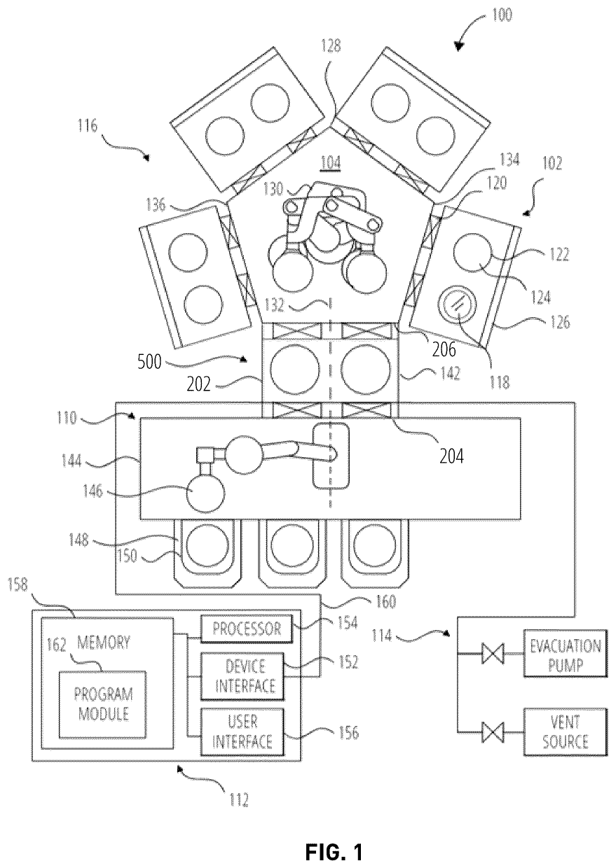

Turning now to the figures, FIG. 1 illustrates a semiconductor processing system 100 of the present disclosure, including a transfer chamber 500 (e.g., a load lock chamber) including apparatus for reducing moisture content within the exemplary transfer chamber 500. The semiconductor processing system 100 includes a process module 102, a back-end transfer module 104, and a transfer chamber 500 (e.g., a load lock chamber) including a housing 202. The semiconductor processing system 100 also includes an equipment front-end module 110 (EFEM), a controller 112, and an evacuation/venting source 114. In the illustrated example the semiconductor processing system 100 includes a cluster-type platform 116 with four (4) process modules configured to deposit/etch a material layer onto/from a substrate 118 using deposition and/or etch processes, such as, atomic layer deposition (ALD), chemical vapor deposition (CVD), plasma-enhanced chemical vapor deposition (PECVD), plasma-enhanced atomic layer deposition (PEALD), atomic layer etch (ALEt) processes, chemical vapor etch (CVE) processes, and plasma based dry-etch processes, for example. This is for illustration and description purposes only and is non-limiting. As will be appreciated by those of skill in the art in view of the present disclosure, semiconductor processing systems configured for other material layer deposition/etch operations as well as semiconductor processing systems configured for other processing operations can also benefit from the present disclosure.

The process module 102 is coupled to the back-end transfer module 104 by a process module gate valve 120. The process module 102 includes a process chamber 122, a heater 124, and a reactant source 126. The process chamber 122 is arranged within the process module 102, houses the heater 124, and is configured to flow a precursor or reactant across the substrate 118 while seated on the heater 124 during deposition/etch of a material layer onto/from the substrate 118. The precursor/reactant source 126 is fluidly coupled to the process chamber 122 and configured to provide the precursor/reactant to the process chamber 122 for deposition/etch of the one or more material layers onto/from the substrate 118. The process module gate valve 120 couples the process module 102 to the back-end transfer module 104 and is configured to provide selective communication between the process chamber 122 and the back-end transfer module 104. In this respect it is contemplated that the process module gate valve 120 can be configured to permit transfer of the substrate 118 between the back-end transfer module 104 and the process module 102 before and after deposition of material layer(s) onto the substrate 118.

In accordance with examples of the disclosure, the process chamber 122 may be a first process chamber and the process module 102 may include one or more second process chambers. For example, the process module 102 may be a dual chamber module having two (2) process chambers or a quad chamber module having four (4) process chambers (not shown). In accordance with certain examples, the process module gate valve 120 may be a first process module gate valve and the process module 102 may include a second process module gate valve also coupling the process module 102 to the back-end transfer module 104. It is contemplated that, in certain examples, the reactant may include a reactant or a precursor suitable for deposition/etch of a material layer. It is also contemplated that, in accordance with certain examples, the process module 102 includes a plasma unit configured to provide the reactant to the substrate 118 as a suitable plasma. In this respect the process module 102 may be configured to deposit/etch a material layer onto/from the substrate 118 using a plasma-enhanced deposition/etch technique by way of example.

The back-end transfer module 104 is coupled to a rear face 206 of the housing 202 of the transfer chamber 500 and includes a back-end chamber body 128 and a back-end substrate transfer robot 130. The back-end chamber body 128 is arranged along a transfer axis 132. It is contemplated that the back-end substrate transfer robot 130 be arranged within a passage of the back-end chamber body 128 and supported within the back-end chamber body 128 for movement relative to the back-end chamber body 128 for transfer of substrates, e.g., the substrate 118, between the transfer chamber 500 and the process module 102. In certain examples, the back-end chamber body 128 may have a polygonal shape. In this respect the back-end chamber body 128 may have five sides, fewer than five sides (e.g., a rectangular or square shape), or more than five sides (e.g., a hexagonal shape), and may have the shape of a regular polygon or an irregular polygon.

The equipment front-end module 110 (EFEM) is coupled to a front face 204 of the housing 202 of the transfer chamber 500 and includes an enclosure 144, a front-end substrate transfer robot 146, and one or more load port 148. The enclosure 144 houses the front-end substrate transfer robot 146. The front-end substrate transfer robot 146 is housed within the enclosure 144 for movement relative to the enclosure 144 or transfer of substrates, e.g., the substrate 118, between the one or more load ports 148 and the transfer chamber 500. The one or more load ports 148 are connected to the enclosure 144 and are configured to seat therein a pod 150 housing one or more substrates, prior to and subsequent to deposition/etch of material layers onto/from the substrates. In certain examples, the pod 150 may include a standard mechanical interface pod. In accordance with certain examples, the pod 150 may include a front-opening unified pod. Although shown and described herein as having three (3) load ports it is to be understood and appreciated that equipment front-end module 110 may include fewer or additional load ports and remain within the scope of the present disclosure.

The controller 112 is operably connected to the semiconductor processing system 100 and includes a device interface 152, a processor 154, a user interface 156, and a memory 158. The device interface 152 couples the processor 154 to the semiconductor processing system 100, for example, through (or over) a wired or wireless link 160. The processor 154 is operably connected to the user interface 156 and is disposed in communication with the memory 158. The memory 158 includes a non-transitory machine-readable medium having a plurality of program module 162 recorded thereon containing instructions that, when read by the processor 154, cause the processor 154 to execute certain operations. Among the operations are operations for reducing moisture within the transfer chamber 500, as will be described below.

In some embodiments, the semiconductor processing system 100 can include a transfer chamber 500, the transfer chamber 500 including apparatus for preventing moisture entering the transfer chamber.

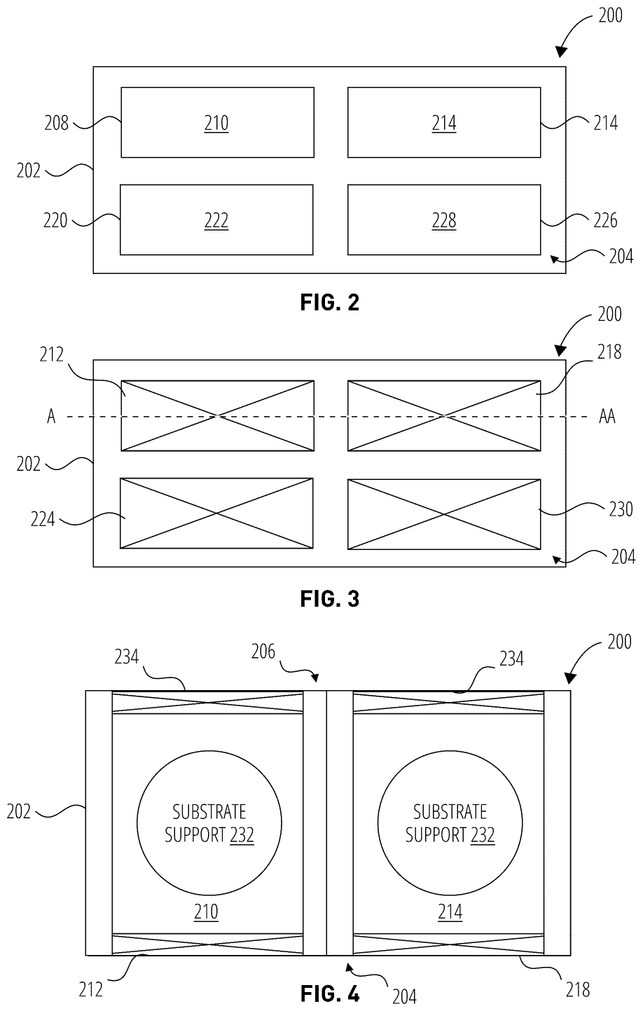

FIG. 2, FIG. 3, and FIG. 4 illustrate various views of an exemplary transfer chamber 200 prior to the addition of the various components/apparatus configured for reducing moisture content within the transfer chamber 200. In more detail, FIG. 2 illustrates a front view of the transfer chamber 200 with the various gate valves set in the open position, FIG. 3 illustrates a front view of the transfer chamber 200 with the various gate valves set in the closed position, and FIG. 4 illustrates a cut-away plan view of the transfer chamber 200.

In accordance with examples of the disclosure and with reference to FIGS. 2-4 the transfer chamber 200 comprises a housing 202 including a front face 204, and a rear face 206.

In accordance with examples of the disclosure, the housing 202 includes a first opening 208 through which a substrate (not shown) is transferred into a first passage 210. In such examples, a first gate valve 212 is disposed on a front face 204 of the housing 202, wherein the first gate valve 212 is either set to an open position to allow the controlled transfer of a substrate into the first passage 210 through the first opening 208 or is set to a closed position to form a vacuum seal over the first opening 208.

In accordance with additional examples of the disclosure, the housing 202 can include a second opening 214 through which a substrate (not shown) is transferred into a second passage 216. In such examples, the second opening 214 is disposed to a side of the first opening 208. In such examples, a second gate valve 218 is disposed on a front face 204 of the housing 202, wherein the second gate valve 218 is either set to an open position to allow the controlled transfer of a substrate into the second passage 216 through the second opening 214 or is set to a closed position to form a vacuum seal over the second opening 214.

In accordance with additional examples of the disclosure, the housing 202 can include a third opening 220 through which a substrate (not shown) is transferred into a third passage 222. In such examples, the third opening 220 is disposed below the first opening 208. In such examples, a third gate valve 224 is disposed on a front face 204 of the housing 202, wherein the third gate valve 224 is either set to an open position to allow the controlled transfer of a substrate into the third passage 222 through the third opening 220 or is set to a closed position to form a vacuum seal over the third opening 220.

In accordance with further examples of the disclosure, the housing 202 can include a fourth opening through which a substrate (not shown) is transferred into a fourth passage 228. In such examples, the fourth opening 226 is disposed below the second opening 214 and to a side of the third opening 220. In such examples, a fourth gate valve 230 is disposed on a front face 204 of the housing 202, wherein the fourth gate valve 230 is either set to an open position to allow the controlled transfer of a substrate into the fourth passage 228 through the fourth opening 226 or is set to a closed position to form a vacuum seal over the fourth opening 226.

In accordance with examples of the disclosure, each of passages (210, 212, 222, 228) within the transfer chamber 200 include at least one substrate support 232 (as illustrated in FIG. 4). In such examples, the substrate support 232 is constructed and arranged for retaining a substrate within the passages of the transfer chamber. In addition, the rear face 206 of the housing 202 includes one or more rear gate valve 234, wherein each of the one or more passages of the transfer chamber 200 includes a rear gate valve 234 which operates in a similar manner as the gate valves disposed on the front face 204 of the transfer chamber 200 (e.g., gate valves 212, 218, 224, 230).

In some embodiments of the disclosure the transfer chamber is a single chamber transfer chamber and includes a first opening 208, a single passage (e.g., first passage 210). In such embodiments, the transfer chamber includes a first gate valve 212, a substrate support 232, and a rear gate valve 234.

In some embodiments of the disclosure the transfer chamber is dual chamber transfer chamber and includes a first opening 208 and a second opening 214, the second opening 214 being disposed to a side of the first opening 208. In such embodiments, the dual chamber transfer chamber includes a first passage 210 (controlled by gate valves 212 and 234) and a second passage 216 (controlled by gate valves 218 and 234), wherein a substrate support 232 is disposed in each of the first passage 210 and the second passage 216).

In some embodiments of the disclosure the transfer chamber is dual chamber transfer chamber and includes a first opening 208 and a third opening 220, the third opening 220 being disposed to below the first opening 208. In such embodiments, the dual chamber transfer chamber includes a first passage 210 (controlled by gate valves 212 and 234) and a third passage 222 (controlled by gate valves 224 and 234), wherein a substrate support 232 is disposed in each of the first passage 210 and the third passage 222).

In some embodiments of the disclosure the transfer chamber is quad chamber transfer chamber. In such embodiments, the transfer chamber includes upper dual chambers where the upper dual chambers include a first opening 208 and a second opening 214, the second opening 214 being disposed to a side of the first opening 208. In such embodiments, the upper chamber includes a first passage 210 (controlled by gate valves 212 and 234) and a second passage 216 (controlled by gate valves 218 and 234), wherein a substrate support 232 is disposed in each pf the first passage 210 and the second passage 216). In such embodiments, the transfer chamber also includes lower dual chambers where the lower dual chambers include a third opening 220 and a fourth opening 226, the third opening 220 disposed below the first opening 208 and the fourth opening being disposed to a side of the third opening 220 and below the second opening 214. In such embodiments, the lower dual chamber includes a third passage 222 (controlled by gate valves 224 and 234) and a fourth passage 228 (controlled by gate valves 230 and 234), wherein a substrate support 232 is disposed in each of the third passage 222 and the fourth passage 228.

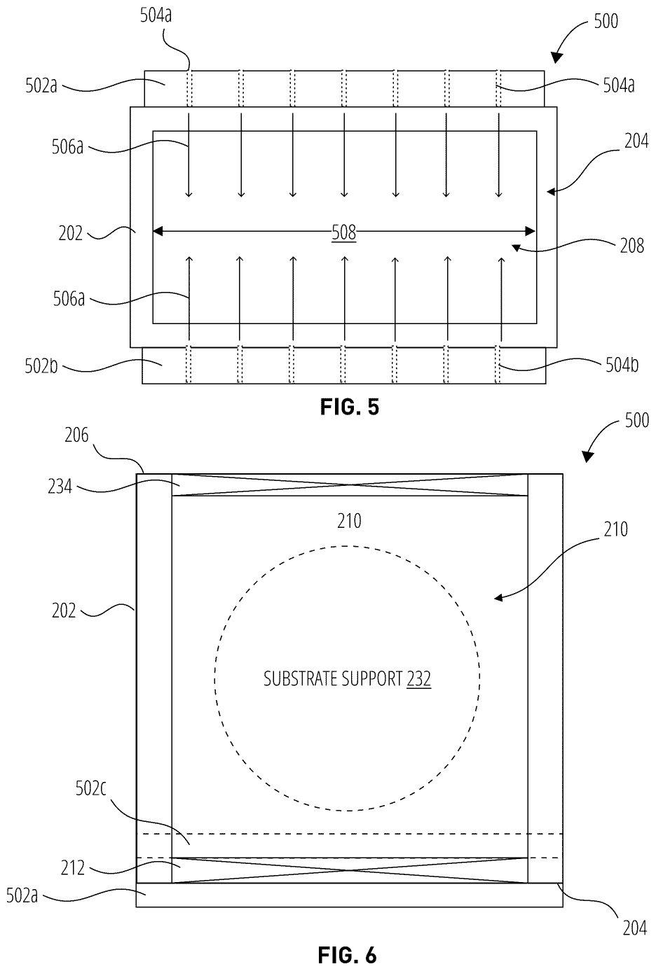

FIG. 5 and FIG. 6 illustrate views of a transfer chamber 500 in accordance with one or more embodiments of the present disclosure. FIG. 5 illustrates a front view of the transfer chamber 500 with a first gate valve 212 in the open position and FIG. 6 illustrates a plan view of the transfer chamber 500.

In accordance with examples of the disclosure, the transfer chamber 500 comprises a housing 202, a front face 204, a rear face 206, a first opening 208, a first gate valve 212, a rear gate valve 234, and a first passage 210 including at least one substrate support 232 as described above.

In accordance with examples of the disclosure, the transfer chamber 500 includes one or more gas distributors (502a, 502b, 502c) disposed on the housing 202 proximate to the first gate valve 212. In some embodiments, the one or more gas distributors are disposed within the first passage 210 (as illustrated by the dashed line of gas distributor 502c of FIG. 6). In some embodiments, the one or more gas distributors are disposed on an external face of the housing (as illustrated by the gas distributor 502a and the gas distributor 502b). In such embodiments, the gas distributors can be disposed on the front face 204 of the housing 202, as illustrated in FIG. 5 and FIG. 6 by the gas distributors 502a and 502b.

In accordance with examples of the disclosure, the one or more gas distributors (502a, 502b, 502c) may include a flow prevention feature (also shown by 502a in FIG. 5) to prevent backflow into the transfer chamber 500, such as a baffle or brim structure. The flow prevention feature may be affixed the back wall of the transfer chamber 500 at a location above the first gate valve 212 and/or the second gate valve 218. The flow prevention feature may protrude from the back wall of the transfer chamber 500 and operate to generate a localized region of high pressure recirculation, the localized region of high pressure recirculation in turn discouraging fluid communication from the interior of the transfer chamber 500 through either (or both) the first gate valve 212 and the second gate valve 218. Advantageously, this can limit moisture introduction into the loadlock upon transfer of wafers through either (or both) the first gage valve 212 and the second gate valve 218, limiting contamination otherwise potentially associated with such moisture. To further advantage, the flow prevention feature may limit the amount of nitrogen otherwise require to maintain a barrier between the EFEM 110 and the transfer 500.

In accordance with examples of the disclosure, the one or more gas distributors (502a, 502b, 502c) can include a plurality of gas directing channels 504a, 504b. The gas directing channels 504a, 504b are illustrated as dashed channels in FIG. 5 to denote that the gas directing channels are internal channels within the gas distributors (see gas distributors 502a, 502b). In other examples, the gas distributors include a single gas directing channel. In other examples, the gas directing channels comprises apertures disposed in a face of the gas distributors 502a, 502b. In other examples, the gas distributors include one or more gas directing channels. In accordance with examples of the disclosure, the gas directing channels 504a and the gas directing channels 504b are constructed and arranged to direct an inert gas (as indicated inert gas flows 506a and 506b) over the first opening 208 of the housing 202 to form a gas curtain over the first opening 208.

In accordance with examples of the disclosure, the gas distributors are positioned above and/or below the first opening of the housing. In such examples, the plurality of gas directing channels within the gas distributor(s) extend in a vertical direction for directing an inert gas across a width of the first opening. In some embodiments, the transfer chamber 500 includes a gas distributor 502a positioned above the first opening 208 and the gas directing channels 504a, within gas distributor 502a, extend in vertical direction for directing an inert gas downward (denoted by inert gas flow 506a) across a width of the first opening (where the arrow 508 illustrates the width of the first opening). In such embodiments, the gas distributor 502a can include a plurality of gas directing channels 504a which are constructed and arranged to direct an inert gas across the entire width (508) of the first opening 208. In some embodiments, the transfer chamber 500 includes a gas distributor 502b positioned below the first opening 208 and the gas directing channels 504b, within gas distributor 502b, extend in vertical direction for directing an inert gas upward (denoted by inert gas flow 506b) across a width of the first opening (508). In such embodiments, the gas distributor 502b can include a plurality of gas directing channels 504b which are constructed and arranged to direct an inert gas across the entire width (508) of the first opening 208.

In some embodiments, the transfer chamber 500 includes both a gas distributor 502a positioned above the first opening 208 and a gas distributor 502b positioned below the first opening 208. In some embodiments, the transfer chamber 500 includes a gas distributor 502a positioned above the first opening 208 (as described above) and a gas distributor 502b positioned below the first opening 208 (as described above), and an internal gas distributor 502c. In some embodiments, the transfer chamber 500 includes at least one of the gas distributors 502a, 502b, 502c)

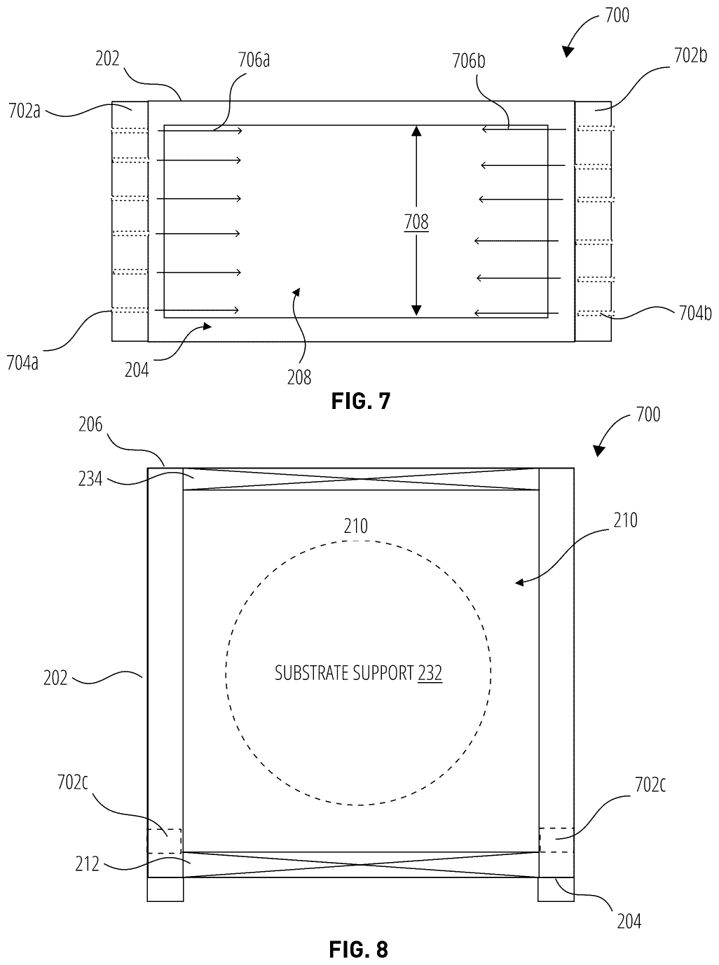

FIG. 7 and FIG. 8 illustrate views of a transfer chamber 700 in accordance with one or more additional embodiments of the present disclosure. FIG. 7 illustrates a front view of the transfer chamber 700 with a first gate valve 212 in the open position and FIG. 8 illustrates a plan view of the transfer chamber 700.

In accordance with examples of the disclosure, the transfer chamber 700 of FIG. 7 and FIG. 8 is the same or similar as that described with reference to FIG. 5 and FIG. 6 with an exception being the configuration of the gas distributors. Therefore the description below is limited to the additional configurations of the gas distributors.

In accordance with examples of the disclosure, the transfer chamber 700 includes one or more gas distributors (702a, 702b, 702c) disposed on the housing 202 proximate to the first gate valve 212. In some embodiments, the one or more gas distributors are disposed within the first passage 210 of the housing 202 (as illustrated by the dashed line of gas distributor 702c of FIG. 8). In some embodiments, the one or more gas distributors are disposed on an external face of the housing, as illustrated by gas distributor 702a and gas distributor 702b. In such embodiments, the gas distributors (702a, 702b) can be disposed on the front face 204 of the housing 202, as illustrated in FIG. 7 and FIG. 8.

In accordance with examples of the disclosure, the one or more gas distributors of transfer chamber 700 include a plurality of gas directing channels 704a, 704b, as described above with reference to gas directing channels 504a, 504b. In accordance with examples of the disclosure, the gas directing channels 704a, 704b are constructed and arranged to direct an inert gas flow (denoted by inert gas flow lines 706a and 706b) over the first opening 208 of the housing 202 to form a gas curtain over the first opening 208.

In accordance with examples of the disclosure, the one or more gas distributors of transfer chamber 700 are positioned on a side of the first opening and the gas directing channels extend in a horizontal direction for directing an inert across the height of the first opening. In such examples, the plurality of gas directing channels within the gas distributor(s) extend in a horizontal direction for directing an inert gas across a height of the first opening.

In some embodiments, the transfer chamber 700 includes a gas distributor 702a positioned to the left of the first opening 208 and the gas directing channels 704a, within gas distributor 702a, extend in a horizontal direction for directing an inert gas toward the first opening 208 (denoted by inert gas flow lines 706a). In such examples, the horizontal gas directing channels direct the inert gas across a height of the first opening (where the arrow 708 illustrates the height of the first opening 208). In such embodiments, the gas distributor 702a can include a plurality of gas directing channels 704a which are constructed and arranged to direct an inert gas across the entire height (708) of the first opening 208.

In some embodiments, the transfer chamber 700 includes a gas distributor 702b positioned to the right of the first opening 208 and the gas directing channels 704b, within gas distributor 702b, extend in a horizontal direction for directing an inert gas toward the first opening 208 (denoted by inert gas flow lines 706b). In such examples, the horizontal gas directing channels direct the inert gas across a height of the first opening (708). In such embodiments, the gas distributor 702b can include a plurality of gas directing channels 704b which are constructed and arranged to direct an inert gas across the entire height (708) of the first opening 208.

In some embodiments, the transfer chamber 700 includes a gas distributor 702c positioned either to the left and/or to the right of the first opening 208 and is disposed within the first passage 210. In such embodiments, the gas distributor 702c includes horizontal gas directing channels as described above. In such embodiments, the gas distributor 702c is the same or similar to gas distributors 702a, and 702b.

In some embodiments, the transfer chamber 700 includes both a gas distributor 702a positioned to the left of the first opening 208 and a gas distributor 702b positioned to the right of the first opening 208. In some embodiments, the transfer chamber 700 includes both gas distributors 702a and 702b as well as one or more internal gas distributors 702c. In some embodiments, the transfer chamber 700 includes at least one of the gas distributors 702a, 702b, 702c).

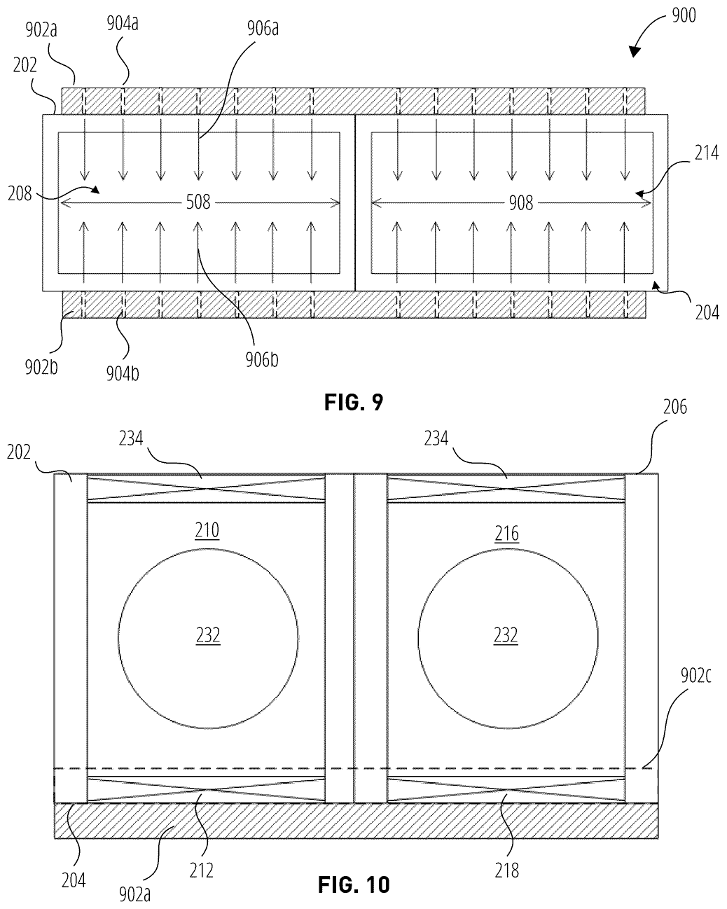

FIG. 9 and FIG. 10 illustrate views of a transfer chamber 900 in accordance with one or more additional embodiments of the present disclosure. FIG. 9 illustrates a front view of the transfer chamber 900 with a first gate valve 212 and a second gate valve 218 in the open position and FIG. 9 illustrates a cut-away plan view of the transfer chamber 900.

In accordance with examples of the disclosure, the transfer chamber 900 comprises a dual chamber transfer chamber as described previously above. In such examples, the transfer chamber 900 includes housing 202, a front face 204, a rear face 206, a first opening 208, a second opening 214, a first gate valve 212, a second gate valve 218, rear gate valves 234, a first passage 210 and a second passage 216 (each including at least one substrate support (now shown) as described above).

In accordance with examples of the disclosure and with reference to FIG. 9, the transfer chamber 900 includes one or more gas distributors (902a, 902b, gas distributor 902c) disposed on the housing 202 proximate to the first gate valve 212 and proximate to the second gate valve 218. In some embodiments, the gas distributors of transfer chamber 900 are disposed within the first passage 210 and the second passage 216 (as illustrated by the dashed line of gas distributor 902c of FIG. 10). In some embodiments, the gas distributors are disposed on an external face of the housing (as illustrated by the gas distributor 902a and gas distributor 902b). In such embodiments, the gas distributors can be disposed on the front face 204 of the housing 202, as illustrated in FIG. 9 by the gas distributors 902a and 902b.

In accordance with examples of the disclosure, the gas distributors (902a, 902b, gas distributor 902c) include a plurality of gas directing channels 904a, 904b, as described above. In accordance with examples of the disclosure, the gas directing channels 904a, 904b are constructed and arranged to direct an inert gas (as indicate inert gate flow 906a, 906b) over both the first opening 208 and the second opening 214 of the housing 202 to form a gas curtain over both the first opening 208 and the second opening 214.

In accordance with examples of the disclosure, the gas distributors are positioned above and/or below the first opening and the second opening of the housing. In such examples, the gas directing channels within the gas distributor(s) extend in a vertical direction for directing an inert gas across a width of the first opening and the width of the second opening. In some embodiments, the transfer chamber 900 includes a gas distributor 902a positioned above the first opening 208 and the second opening 214 and the gas directing channels 904a, within gas distributor 902a, extend in vertical direction for directing an inert gas downward (denoted by inert gas flow lines 906a) across a width of the first opening (508) and across a width of the second opening (wherein the arrow 908 illustrated the width of the second opening). In such embodiments, the gas distributor 902a can include a plurality of gas directing channels 904a which are constructed and arranged to direct an inert gas across the entire width (508, 908) of both the first opening 208 and the second opening 214. In some embodiments, the transfer chamber 900 includes a gas distributor 902b positioned below the first opening 208 and the second opening 214 and the gas directing channels 904b, within gas distributor 902b, extend in vertical direction for directing an inert gas upward (denoted by inert gas flow lines 906b) across a width of the first opening (508) and across a width of the second opening (908). In such embodiments, the gas distributor 902b can include a plurality of gas directing channels 904b which are constructed and arranged to direct an inert gas across the entire width (508, 908) of both the first opening 208 and the second opening 214.

In some embodiments, the transfer chamber 900 includes the gas distributor 902a positioned above the first opening 208 and the second opening 214, and the gas distributor 902b positioned below the first opening 208 and the second opening 214. In some embodiments, the transfer chamber 900 includes the gas distributors 902a and 902b, and an internal gas distributor 902c, where gas distributor 902c can be positioned above and/or below the first and second openings. In some embodiments, the transfer chamber 900 includes at least one of the gas distributors 902a, 902b, 902c.

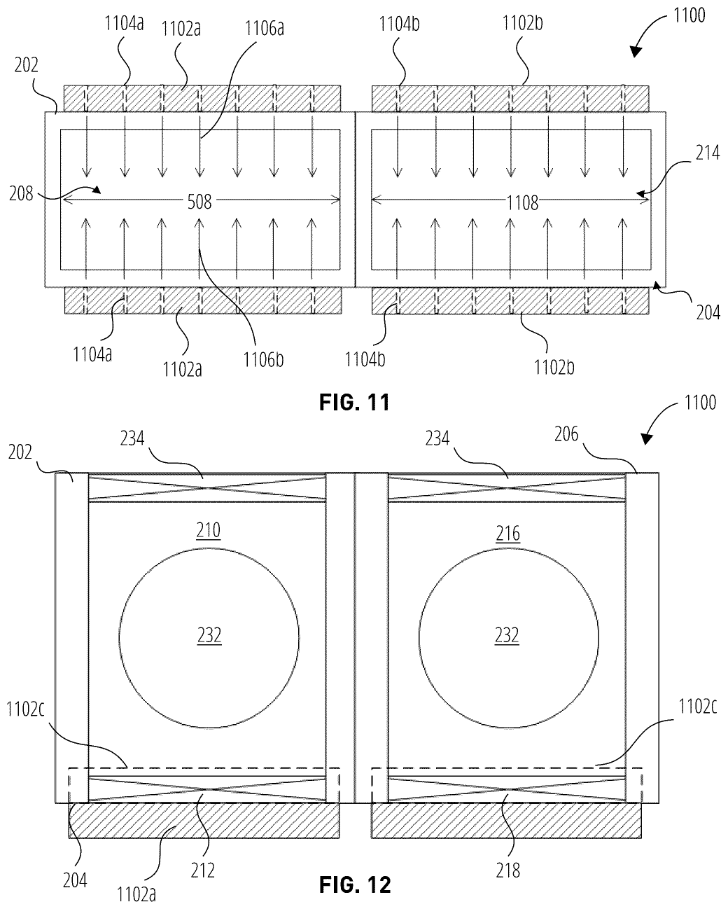

FIG. 11 and FIG. 12 illustrate views of a transfer chamber 1100 in accordance with one or more additional embodiments of the present disclosure. FIG. 11 illustrates a front view of the transfer chamber 1100 with a first gate valve 212 and a second gate valve 218 in the open position and FIG. 9 illustrates a cut-away plan view of the transfer chamber 1100.

In accordance with examples of the disclosure, the transfer chamber 1100 comprises a dual chamber transfer chamber as described previously above. In such examples, the transfer chamber 1100 includes housing 202, a front face 204, a rear face 206, a first opening 208, a second opening 214, a first gate valve 212, a second gate valve 218, rear gate valves 234, a first passage 210 and a second passage 216 (each including at least one substrate support (now shown) as described above).

The configuration of the transfer chamber 1100 is similar to the configuration of transfer chamber 900 with a difference being that the singular gas distributor of transfer chamber 900 (e.g., gas distributors 902a or 902b) are split in two, e.g., a first gas distributor and a second gas distributor. In such example the first gas distributor is positioned above and/or below the first opening and the second gas distributor is positioned above and/or below the second opening.

In more detail and with reference to FIG. 11 and FIG. 12 the transfer chamber 1100 includes a first gas distributor 1102a positioned above and/or below first opening 208 and a second gas distributor 1102b positioned above and/or below the second opening 214. The gas distributors 1102a and 1102b can be disposed on the front face 204 of the housing 202 and/or can be disposed within the first passage 210 and the second passage 216 (as illustrated by the dashed line of gas distributor 1102c of FIG. 12). In some embodiments, the transfer chamber 1100 includes the gas distributors 1102a and 1102b, and one or more internal gas distributors 1102c, where gas distributors 1102a, 1102b, 1102c can be positioned above and/or below the first and second openings. In some embodiments, the transfer chamber 1100 includes the gas distributors 1102a and 1102b, or one or more internal gas distributors 1102c. In addition, gas distributors 1102a, 1102b, and 1102c include plurality of vertically extending gas directing channels (e.g., channels 1104a, 1104b, and 1104c) for directing an inert gas flow (e.g., flows 1106a, 1106b) over both the first opening 208 and the second opening 214, as previously described above.

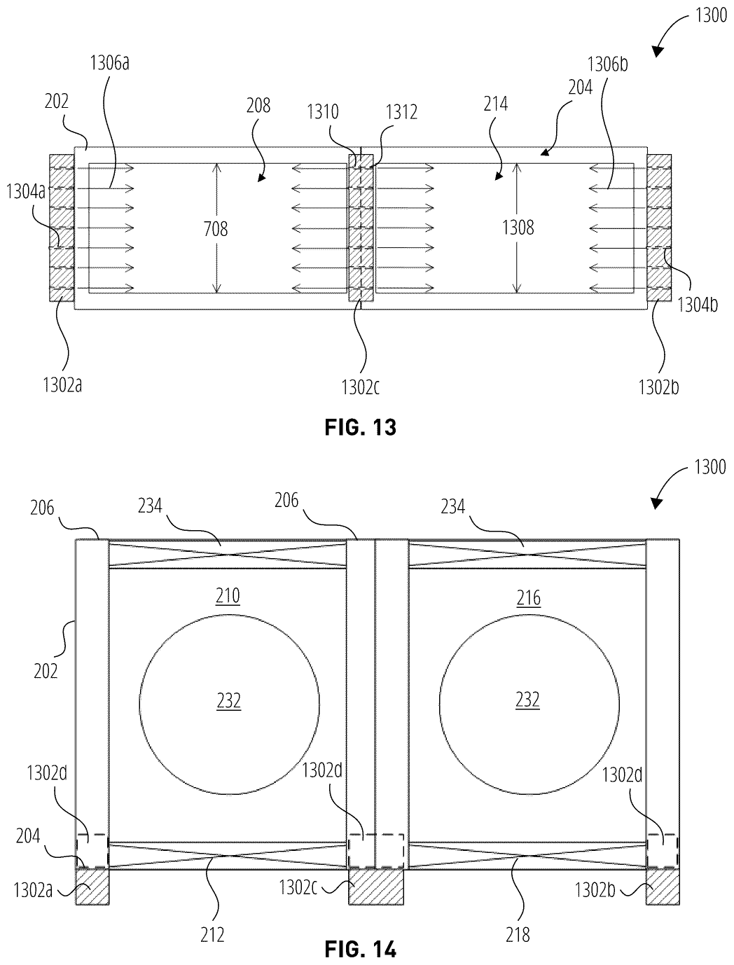

FIG. 13 and FIG. 14 illustrate views of a transfer chamber 1300 in accordance with one or more additional embodiments of the present disclosure. FIG. 13 illustrates a front view of the transfer chamber 1300 with a first gate valve 212 and a second gate valve 218 in the open position and FIG. 9 illustrates a cut-away plan view of the transfer chamber 1300.

In accordance with examples of the disclosure, the transfer chamber 1300 comprises a dual chamber transfer chamber as described previously above. The transfer chamber 1300 of FIG. 13 and FIG. 14 is the same or similar as that described with reference to FIG. 9 and FIG. 10 with an exception being the configuration of the one or more gas distributors. Therefore the description below is limited to the additional configurations of the one or more gas distributors.

In accordance with examples of the disclosure, transfer chamber 1300 includes one or more gas distributors positioned on a side of the first opening and on a side of the second opening. In such examples, the gas directing channels (within the gas distributors) extend in a horizontal direction for directing an inert across the height of the first opening and across the height of the second opening. In such examples, the plurality of gas directing channels within the gas distributor(s) extend in a horizontal direction for directing an inert gas across a height of the first opening and across a height of the second opening.

In some embodiments and with reference to FIG. 13, the transfer chamber 1300 includes a gas distributor 1302a positioned to the left of the first opening 208 and the gas directing channels 1304a, within gas distributor 1302a, extend in a horizontal direction for directing an inert gas toward the first opening 208 (denoted by inert gas flow lines 1306a), as described previously with reference to FIG. 7. In such embodiments, the gas distributor 1302a directs an inert gas across the height of the first opening 208 (where the arrow 708 illustrates the height of the first opening).

In some embodiments, the transfer chamber 1300 of FIG. 13 includes a gas distributor 1302b positioned to right of the second opening 214 and the gas directing channels 1304b, within the gas distributor 1302b, extend in a horizontal direction for directing an inert gas towards the second opening 214 (denoted by inert gas flow lines 1306b). In such embodiments, the gas distributor 1302b directs an inert gas across the height of the second opening 214 (where the arrow 1308 illustrates the height of the second opening).

In some embodiments, the transfer chamber 1300 of FIG. 13 includes both the gas distributor 1302a positioned to the left of the first opening 208 (as described above) and the gas distributor 1302b positioned to right of the second opening 214 (as described above).

In accordance with further examples of the disclosure, transfer chamber 1300 can also include gas distributors positioned between the first opening and the second opening. In such examples, the gas distributor can include first horizontal gas directing channels and second horizontal gas directing channels, the first horizontal gas directing channels extending in a horizontal direction for directing the inert gas across a height of the first opening and the second horizontal gas directing channels extending in a horizontal direction for directing the inert gas across a height of the second opening. In such examples, the first horizontal gas directing channels and the second horizontal gas directing channels are constructed and arranged for directing the inert gas in opposing directions. In accordance with such examples FIG. 13 illustrates a gas distributor 1302c positioned between the first opening 208 and the second opening 214. In such examples, the gas distributor 1302c includes first horizontal gas directing channels 1310 extending in a horizontal direction for directing an inert gas across the height (708) of the first opening 208. In such examples, the gas distributor 1302c includes second horizontal gas directing channels 1312 extending in a horizontal direction for directing an inert gas across the height (1308) of the second opening 214. In such examples, the first horizontal gas directing channels 1310 and the second horizontal gas directing channels 1312 are constructed and arranged for directing inert gas in opposing directions. In some embodiments, the gas distributor 1302c comprises a single gas distributor including both the first horizontal gas directing channels and second horizontal gas directing channels. In some embodiments, the gas distributor 1302c comprises two gas distributors, a first gas distributor (of 1302c) including the first horizontal gas directing channels 1310 and the second gas distributor (of 1302c) including the second horizontal gas directing channels 1312.

In some embodiments, the transfer chamber 1300 of FIG. 13 includes the gas distributor 1302a positioned to the left of the first opening 208 (as described above), the gas distributor 1302b positioned to right of the second opening 214 (as described above), and the gas distributor 1302c positioned between the first opening 208 and the second opening 214 (as described above). The gas distributors 1302a, 1302b, and 1302c can be disposed on the front face 204 of the housing 202 and/or can be disposed within the first passage 210 and the second passage 216 (as illustrated by the dashed line of gas distributors 1302d of FIG. 14). In some embodiments, the transfer chamber 1300 includes at least one of the gas distributors 1302a, 1302b, 1302c, and 1302d.

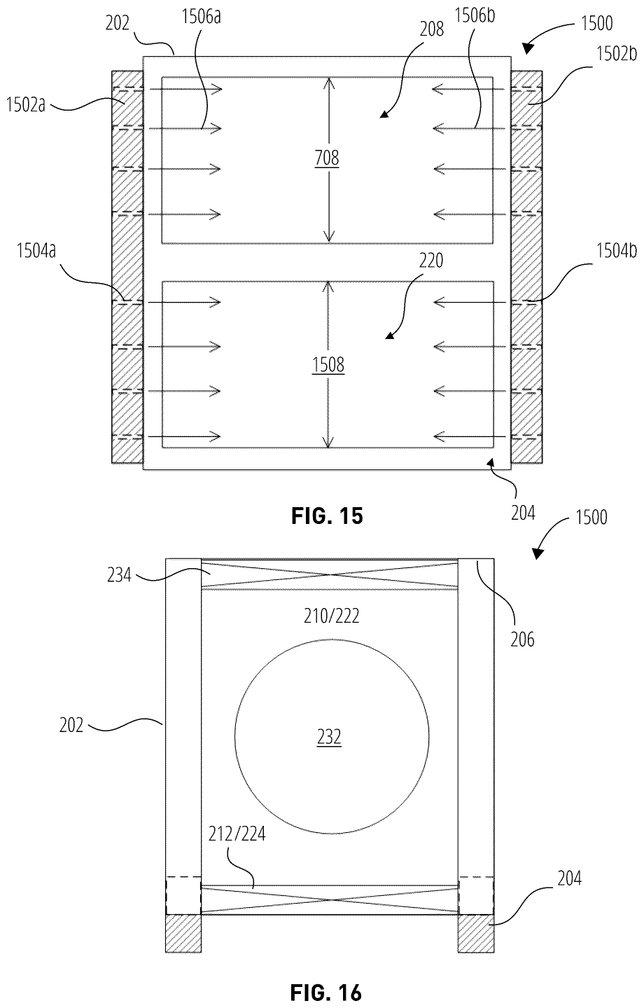

FIG. 15 and FIG. 16 illustrate views of a transfer chamber 1500 in accordance with one or more additional embodiments of the present disclosure. FIG. 15 illustrates a front view of the transfer chamber 1500 with a first gate valve 212 and a third gate valve 224 in the open position and FIG. 16 illustrates a cut-away plan view of the transfer chamber 1500. It is noted that although transfer chamber 1500 comprises two opening, two passages, etc., the lower opening is referred to below as the third opening, and the lower passage is referred to below as the third passage, to differentiate from the previous dual chamber examples given above. In addition, the cut-away plan view of the transfer chamber in FIG. 16 illustrates only the upper chamber, but it should be appreciated that the lower chamber configuration is the same or similar to that illustrated in FIG. 16.

In accordance with examples of the disclosure, the transfer chamber 1500 comprises a dual chamber transfer chamber comprising an upper chamber including a first opening 208 and a lower chamber including a third opening 220, the third opening 220 being disposed below the first opening 208. In such examples, the transfer chamber 1500 includes housing 202, a front face 204, a rear face 206, a first opening 208, a third opening 220, a first gate valve 212, a third gate valve 224, rear gate valves 234, a first passage 210 and a third passage 222 (each including at least one substrate support (now shown) as described above).

In accordance with examples of the disclosure, the transfer chamber 1500 includes one or more gas distributors (1502a, 1502b, 1502c) disposed on the housing 202 proximate to the first gate valve 212 and the third gate valve 224. In some embodiments, the gas distributors are disposed within the first passage 210 and the third passage 222 of the housing 202 (as illustrated by the dashed line of gas distributors 1502c of FIG. 16). In some embodiments, the gas distributors are disposed on an external face of the housing, as illustrated by gas distributor 1502a and gas distributor 1502b. In such embodiments, the gas distributors (1502a, 1502b) can be disposed on the front face 204 of the housing 202, as illustrated in FIG. 15 and FIG. 16.

In accordance with examples of the disclosure, the gas distributors of transfer chamber 1500 include a plurality of gas directing channels 1504a and 1504b, as described previously. In accordance with examples of the disclosure, the gas directing channels 1504a and 1504b are constructed and arranged to direct an inert gas flow (denoted by inert gas flow lines 1506a and 1506b) over the first opening 208 and the third opening 220 of the housing 202 to form a gas curtain over both the first opening 208 and the third opening 220.

In accordance with examples of the disclosure, the gas distributors of transfer chamber 1500 are positioned on a side of the first opening and the third opening and the gas directing channels extend in a horizontal direction for directing an inert across the height of the first opening and across the height of the third opening. In such examples, the plurality of gas directing channels within the gas distributor(s) extend in a horizontal direction for directing an inert gas across a height of the first opening and third opening.

In some embodiments, the transfer chamber 1500 includes a gas distributor 1502a positioned to the left of the first opening 208 and the third opening 220, and the gas directing channels 1504a, within gas distributor 1502a, extend in a horizontal direction for directing an inert gas toward the first opening 208 and the third opening 220 (denoted by inert gas flow lines 1506a). In such examples, the horizontal gas directing channels direct the inert gas across a height of the first opening 208 (where the arrow 708 illustrates the height of the first opening) and across a height of the third opening 220 (where the arrow 1508 illustrates the height of the third opening). In such embodiments, the gas distributor 1502a can include a plurality of gas directing channels 1504a which are constructed and arranged to direct an inert gas across the entire height (708) of the first opening 208 and across the entire height (1508) of the third opening 220.

In some embodiments, the transfer chamber 1500 includes a gas distributor 1502b positioned to the right of the first opening 208 and the third opening 220, and the gas directing channels 1504b, within gas distributor 1502b, extend in a horizontal direction for directing an inert gas toward the first opening 208 and the third opening 220 (denoted by inert gas flow lines 1506b). In such examples, the horizontal gas directing channels direct the inert gas across a height of the first opening (708) and across a height of the third opening (1508). In such embodiments, the gas distributor 1502b can include a plurality of gas directing channels 1504b which are constructed and arranged to direct an inert gas across the entire height (708) of the first opening 208 and across the entire height (1508) of the third opening 220.

In some embodiments, the transfer chamber 1500 includes a number of gas distributors 1502c disposed within the first passage 210 and the third passage 222 and positioned either to the left and/or to the right of the first opening 208 and the third opening 220. In such embodiments, the gas distributors 1502c includes horizontal gas directing channels as described above. In such embodiments, the gas distributors 1502c is the same or similar to gas distributors 1502a and 1502b.

In some embodiments, the transfer chamber 1500 includes both a gas distributor 1502a positioned to the left of the first opening 208 and the third opening 220, and a gas distributor 1502b positioned to the right of the first opening 208 and the third opening 220. In some embodiments, the transfer chamber 1500 includes both gas distributors 1502a and 1502b as well as one or more internal gas distributors 1502c. In some embodiments, the transfer chamber 1500 includes at least one of the gas distributors 1502a, 1502b, and 1502c.

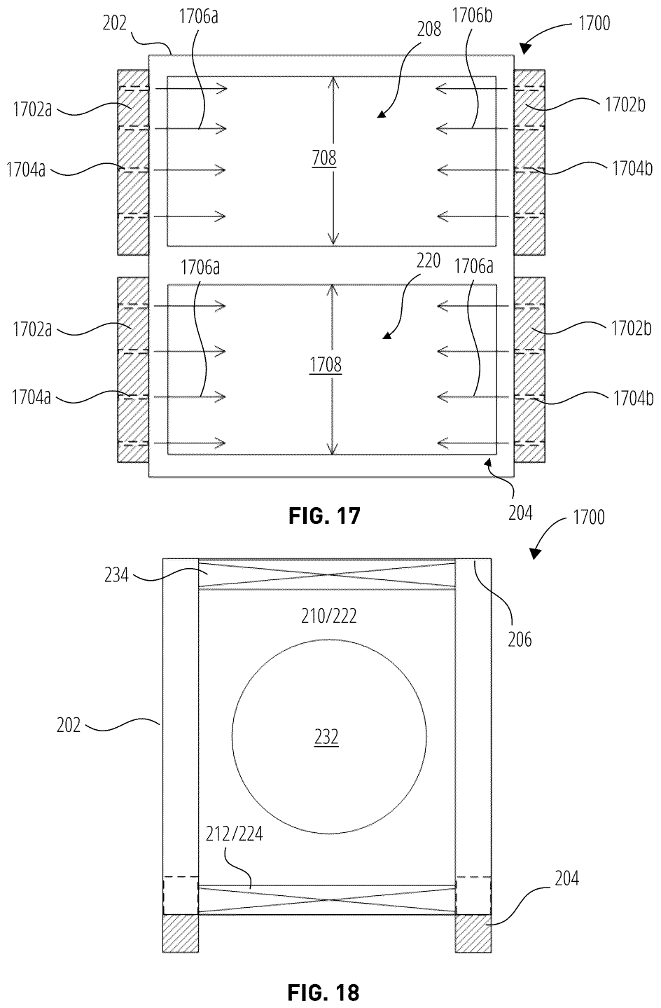

FIG. 17 and FIG. 18 illustrate views of a transfer chamber 1700 in accordance with one or more additional embodiments of the present disclosure. FIG. 17 illustrates a front view of the transfer chamber 1700 with a first gate valve 212 and a third gate valve 224 in the open position and FIG. 16 illustrates a cut-away plan view of the transfer chamber 1700. The configuration of the transfer chamber 1700 is similar to the configuration of transfer chamber 1500 (FIGS. 15-16) with a difference being that the singular gas distributors of transfer chamber 1500 (e.g., gas distributors 1502a or 1502b) are split in two, e.g., split into first gas distributors and second gas distributors. In such example the first gas distributors are positioned to the left of the first opening and the third opening and the second gas distributors are positioned to the right of the first opening and third opening.

In more detail and with reference to FIG. 17 and FIG. 18 the transfer chamber 1700 includes first gas distributors 1702a positioned to the left of the first opening 208 and third opening 220 and second gas distributors 1702b positioned to the right of the first opening 208 and third opening 220. First gas distributors 1702a include gas directing channels 1704a, within first gas distributor 1702a, which extend in a horizontal direction for directing an inert gas toward the first opening 208 and the third opening 220 (denoted by inert gas flow lines 1706a). In such embodiments, the first gas distributors 1702a direct an inert gas across the height (708) of the first opening 208 and across the height (1708) of the third opening 220. Second gas distributors 1702b include gas directing channels 1704b, within second gas distributors 1702b, which extend in a horizontal direction for directing an inert gas toward the first opening 208 and the third opening 220 (denoted by inert gas flow lines 1706b). In such embodiments, the second gas distributors 1702b direct an inert gas across the height (708) of the first opening 208 and across the height (1708) of the third opening 220.

In some embodiments, the transfer chamber 1700 includes both first gas distributors 1702a and second gas distributors 1702b as well as one or more internal gas distributors 1702c. In some embodiments, the transfer chamber 1700 includes at least one of the gas distributors 1702a, 1702b, 1702c.

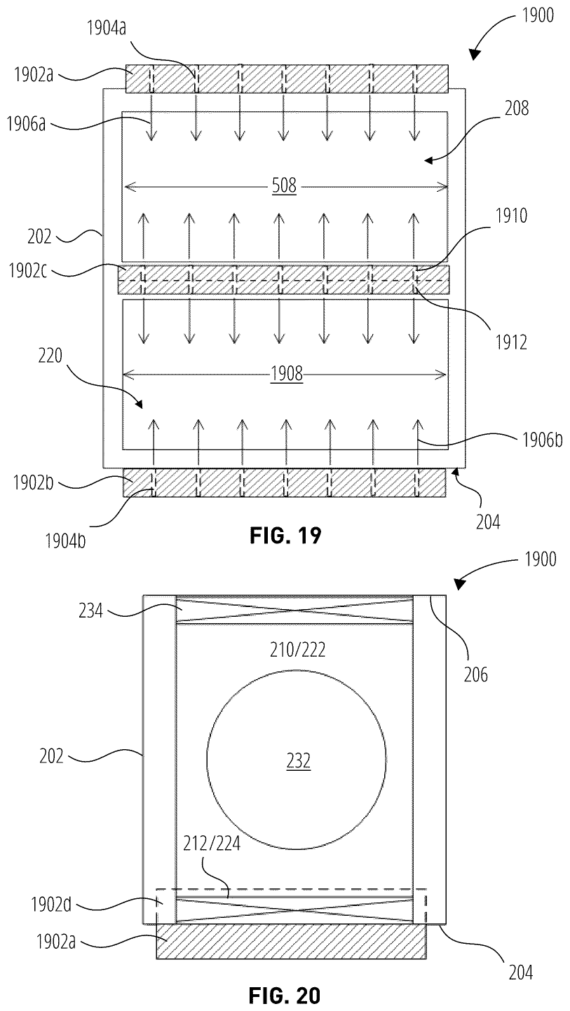

FIG. 19 and FIG. 20 illustrate views of a transfer chamber 1900 in accordance with one or more additional embodiments of the present disclosure. FIG. 19 illustrates a front view of the transfer chamber 1900 with a first gate valve 212 and a third gate valve 224 in the open position and FIG. 20 illustrates a cut-away plan view of the transfer chamber 1900. The configuration of the transfer chamber 1900 is similar to the configuration of transfer chamber 1500 (FIGS. 15-16) with a difference being that one or more gas distributors are positioned horizontal above and/or below the first opening and the third housing.

In accordance with examples of the disclosure, transfer chamber 1900 comprises a dual chamber transfer chamber as described previously above. The transfer chamber 1900 of FIG. 19 and FIG. 20 is the same or similar as that described with reference to FIG. 15 and FIG. 17 with an exception being the configuration of the one or more gas distributors. Therefore the description below is limited to the additional configurations of the one or more gas distributors.

In accordance with examples of the disclosure, transfer chamber 1900 includes one or more gas distributors positioned above and or below the first opening and the third opening. In such examples, the gas directing channels (within the gas distributors) extend in a vertical direction for directing an inert across the width of the first opening and across the width of the third opening.

In some embodiments and with reference to FIG. 19 and FIG. 20, the transfer chamber 1900 includes a gas distributor 1902a positioned above the first opening 208 and the gas directing channels 1904a, within gas distributor 1902a, extend in a vertical direction for directing an inert gas downward toward the first opening 208 (denoted by inert gas flow lines 1906a). In such embodiments, the gas distributor 1902a directs an inert gas across the width of the first opening 208 (708).

In some embodiments, the transfer chamber 1900 of FIG. 19 and FIG. 20 includes a gas distributor 1902b positioned below the third opening 220 and the gas directing channels 1904b, within the gas distributor 1902b, extend in a vertical direction for directing an inert gas upward towards the third opening 220 (denoted by inert gas flow lines 1906b). In such embodiments, the gas distributor 1902b directs an inert gas across the width of the third opening 220 (1908).

In some embodiments, the transfer chamber 1900 of FIG. 19 and FIG. 20 includes both the gas distributor 1902a positioned above the first opening 208 (as described above) and the gas distributor 1902b positioned below of the third opening 220 (as described above).

In accordance with further examples of the disclosure, transfer chamber 1900 can also include gas distributors positioned between the first opening and the third opening. In such examples, the gas distributor can include first vertical gas directing channel and second vertical gas directing channels, the first vertical gas directing channel extending in a vertical direction for directing the inert gas across a width of the first opening and the second vertical gas directing channels extending in a vertical direction for directing the inert gas across a width of the third opening 220. In such examples, the first vertical gas directing channel and the second vertical gas directing channels are constructed and arranged for directing the inert gas in opposing directions. In accordance with such examples FIG. 19 illustrates a gas distributors 1902c positioned between the first opening 208 and the third opening 220. In such examples, the gas distributors 1902c includes first vertical gas directing channel 1910 including gas directing channels 1904c extending in a vertical direction for directing an inert gas upward across the width (508) of the first opening 208. In such examples, the gas distributor 1302c includes second vertical gas directing channels 1912 extending in a vertical direction for directing an inert gas downward across the width (1908) of the third opening 220. In such examples, the first vertical gas directing channel 1910 and the second vertical gas directing channels 1912 are constructed and arranged for directing inert gas in opposing directions (i.e., up and down). In some embodiments, the gas distributors 1902c comprises a single gas distributor including both the first vertical gas directing channels and second vertical gas directing channels. In some embodiments, the gas distributors 1902c comprises two gas distributors, a first gas distributor (of 1902c) including the first vertical gas directing channels 1910 and the second gas distributor (of 1902c) including the second vertical gas directing channels 1912.

In some embodiments, the transfer chamber 1900 of FIG. 19 and FIG. 20 includes the gas distributor 1902a positioned above the first opening 208 (as described above), the gas distributor 1902b positioned below the third opening 220 (as described above), and the gas distributors 1902c positioned between the first opening 208 and the third opening 220 (as described above). The gas distributors 1902a, 1902b, and 1902c can be disposed on the front face 204 of the housing 202 and/or can be disposed within the first passage 210 and the third passage 222 (as illustrated by the dashed lines of gas distributors 1902d of FIG. 20). In some embodiments, the transfer chamber 1900 includes at least one of the gas distributors 1902a, 1902b, 1902c, and 1902d.

In accordance with examples of the disclosure, the transfer chamber can comprise a quad chamber transfer chamber. In such examples, the transfer chamber includes upper dual chambers including a first opening and a second opening, the second opening being disposed to a side of the first opening. In such examples, the upper chamber includes a first passage and a second passage. In such examples, the transfer chamber also includes lower dual chambers including a third opening and a fourth opening, the third opening being disposed below the first opening and the fourth opening being disposed to a side of the third opening and below the second opening. In such embodiments, the lower dual chamber includes a third passage and a fourth passage. In such examples, the various configurations (and combinations thereof) of the gas distributors described above can be employed to prevent moisture from entering the first passage, the second passage, the third passage, and the fourth passage of the quad chamber transfer chamber. The following description provides a number of non-limiting examples of configurations that can be employed with quad chamber transfer chambers, but it should evident that additional configurations are within the scope of the present disclosure.

FIG. 21 illustrates a front view of a transfer chamber 2100 including a housing 202 having a front face 204 and including a first opening 208 and a second opening 214 (together comprising the upper transfer chamber) as well a third opening 220 and a fourth opening 226 (together comprising the lower transfer chamber). Each opening (208, 214, 220, and 226) of transfer chamber 2100 has an associated gate valve, passage, substrate support, and rear gate valve as previously described above. In accordance with examples of the disclosure, transfer chamber 2100 includes gas distributors 2102a, 2102b, 2102c, 2102d, 2102e, and 2102f.

In some embodiments, gas distributors 2102a and 2102b are positioned to the left side of the first opening 208 and the third opening 220 respectively, and include gas directing channels 2104a and 2104b for directing an inert gas across the first opening 208 and the third opening 220. In some embodiments, gas distributors 2102a and gas distributor 2102b can be replaced with a single gas distributor that spans both the first opening 208 and the third opening 220, as illustrated and described with reference to FIG. 15.

In some embodiments, gas distributors 2102e and 2102f are positioned to the right side of the second opening 214 and the fourth opening 226 respectively, and include gas directing channels 2104e and 2104f for directing an inert gas across the second opening 214 and the fourth opening 226. In some embodiments, gas distributor 2102e and gas distributor 2102f can be replaced with a single gas distributor that spans both the second opening 214 and the fourth opening 226, as illustrated and described above.

In some embodiments, gas distributors 2102c is positioned between the first opening 208 and the second opening 214, and the gas distributor 2102d is positioned between third opening 220 and fourth opening 226. In such embodiments, gas distributors 2102c and 2102d include gas directing channels for directing an inert gas across first, second, third and fourth opening 208, 214, 220, and 226. In some embodiments, both gas distributors 2102c and 2102d are the same as the gas distributor 1302c of FIG. 13 and can both include first horizontal gas directing channels and second horizontal gas directing channels as described above.

In some embodiments, the transfer chamber 2100 can include the internal equivalents of gas distributors 2102a, 2102b, 2102c, 2102d, 2102e, and 2102f as described above. In some embodiments, the transfer chamber 2100 includes at least gas distributors 2102a and 2102b. In some embodiments, the transfer chamber 2100 includes at least gas distributors 2102e and 2102f. In some embodiments, the transfer chamber 2100 includes at least gas distributors 2102c and 2102d.

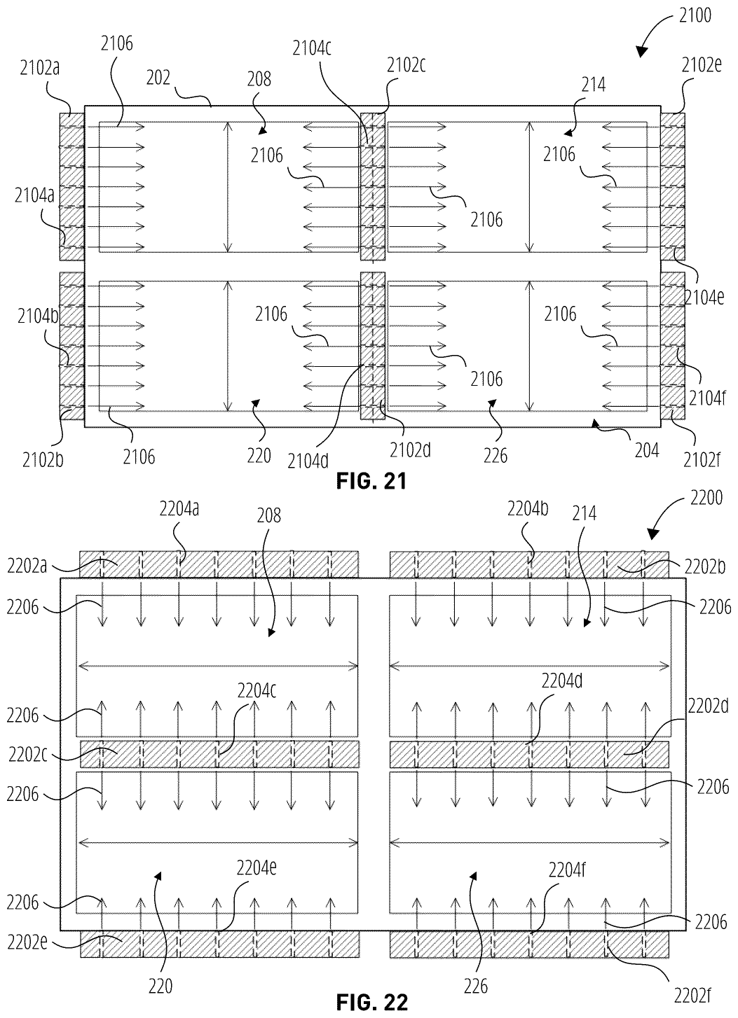

FIG. 22 illustrates a further example of a transfer chamber configuration for a quad chamber transfer chamber, as described above. In accordance with examples of the disclosure transfer chamber 2200 includes gas distributors 2202a, 2202b, 2202c, 2202d, 2202e, and 2202f.

In some embodiments, gas distributors 2202a and 2202b are positioned above the first opening 208 and the second opening 214 respectively, and include gas directing channels gas directing channel 2204a and 2204b for directing an inert gas across the first opening 208 and the second opening 214. In some embodiments, gas distributor 2202a and gas distributor 2202a can be replaced with a single gas distributor that spans both the first opening 208 and the second opening 214, as illustrated and described with reference to FIG. 9.

In some embodiments, gas distributors 2202e and 2202f are positioned below the third opening 220 and the fourth opening 226 respectively, and include gas directing channels gas directing channel 2204e and 2204f for directing inert gas flow 2206 across the third opening 220 and the fourth opening 226. In some embodiments, gas distributors 2202e and gas distributor 2204f can be replaced with a single gas distributor that spans both the third opening 220 and the fourth opening 226, as illustrated and described with reference to FIG. 9.

In some embodiments, gas distributors 2202c is positioned between the first opening 208 and the third opening 220, and the gas distributor 2202d is positioned between second opening 214 and fourth opening 226. In such embodiments, gas distributors 2202c and 2202d include gas directing channels for directing an inert gas across the first, second, third and fourth opening 208, 214, 220, and 226. In some embodiments, both gas distributors 2202c and 2202d are the same as gas distributors 1902c of FIG. 19 and can both include first vertical gas directing channels and second vertical gas directing channels as described above.

In some embodiments, the transfer chamber 2200 can include the internal equivalents of gas distributors 2202a, 2202b, 2202c, 2202d, 2202e, and 2202f, as described above. In some embodiments, the transfer chamber 2200 includes at least gas distributors 2202a and 2202b. In some embodiments, the transfer chamber 2200 includes at least gas distributors 2202e and 2202f. In some embodiments, the transfer chamber 2200 includes at least gas distributors 2202c and 2202d.

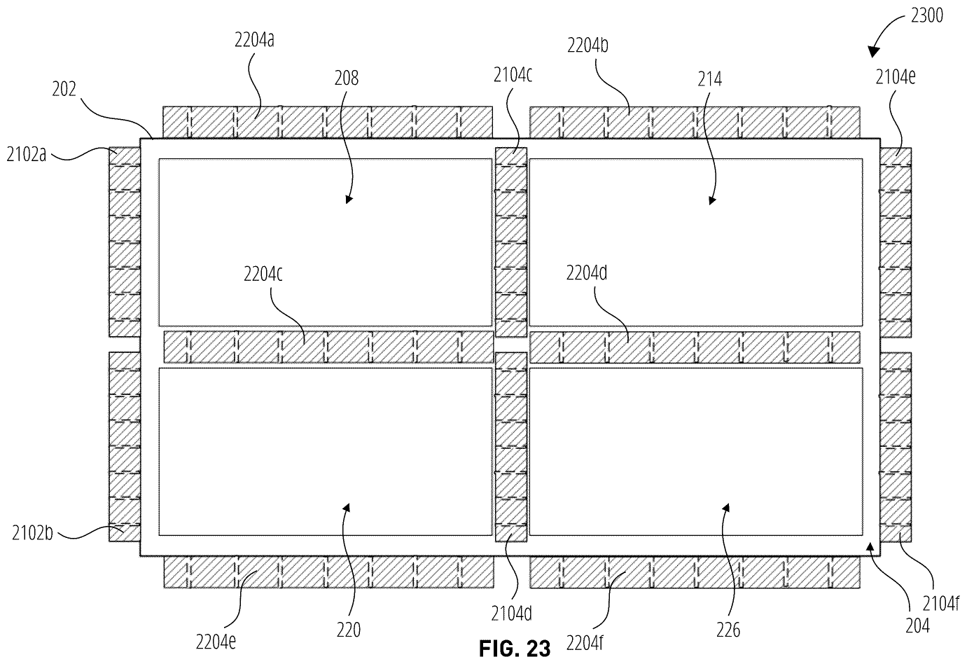

FIG. 23 illustrates a further example of a transfer chamber configuration for a quad chamber transfer chamber, as described above. In accordance with examples of the disclosure, transfer chamber 2300 includes a combination of the gas distributors of transfer chamber 2100 (FIG. 21) and the gas distributors of transfer chamber 2200 (FIG. 22), i.e., gas distributors 2102a, 2102b, 2102c, 2102d, 2102e, 2102f, and gas distributors 2202a, 2202b, 2202c, 2202d, 2202e, and 2202f, as described in detail above.

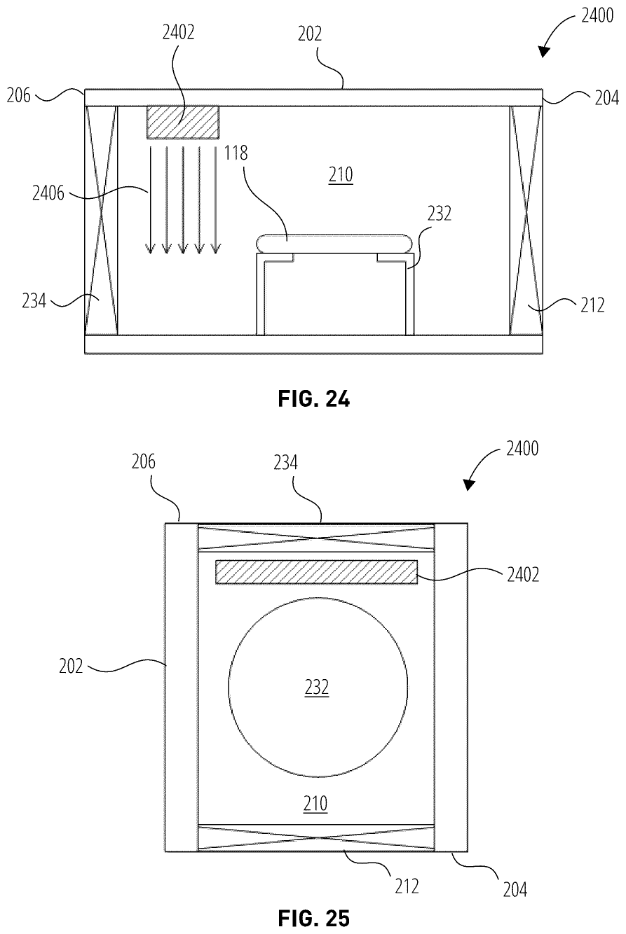

The various embodiments of the disclosure also provide transfer chambers including one or more gas diffusers for preventing moisture from entering the transfer chamber. FIG. 24 and FIG. 25 illustrate views of a transfer chamber 2400 including a gas diffuser in accordance with one or more embodiments of the present disclosure. FIG. 24 illustrates a cut-away side view of the transfer chamber 2400 and FIG. 25 illustrates a cut-away plan view of the transfer chamber 2400.

In accordance with examples of the disclosure and with reference to FIG. 24 and FIG. 25, a transfer chamber 2400 includes a housing 202, a front face 204, a rear face 206, a first gate valve 212, a rear gate valves 234, a first passage 210, a substrate support 232 for retaining substrate 118. In some embodiments, the transfer chamber 2400 includes a gas diffuser 2402 positioned on an upper portion of the housing 202, as illustrated in FIG. 24, however the gas diffuser 2402 can be positioned in other locations within the transfer chamber 2400. In such examples, the gas diffuser 2402 is constructed and arranged to provide a flow of inert gas (as indicated by flow arrows 2406) into the first passage within the housing 202. In some embodiments the gas diffuser 2402 is positioned proximate to the rear gate valve 234. In some embodiments the gas diffuser 2402 is positioned proximate to the first gate valve 212 (i.e., the front gate valve).

In accordance with examples of the disclosure, the gas diffuser can be configured to introduced an inert gas into the first passage and thereby provide an over pressure within the transfer chamber 2400 compared with an adjoining chamber (not shown) coupled to the front face 204 of the housing 202. In such examples, the over pressure within the transfer chamber 2400 prevents moisture from entering the transfer chamber 2400 upon opening of the first gate valve 212. In accordance with examples of the disclosure, the gas diffuser 2402 of FIG. 24 and FIG. 25 can be employed in combination with any of the proceeding transfer chamber configurations to prevent moisture from entering the transfer chambers of the present disclosure.

In accordance with examples of the disclosure, the transfer chambers of the present disclosure (i.e., transfer chambers 500, 700, 900, 1100, 1300, 1500, 1700, 1900, 2100, 2200, 2300, and 2400) can be utilized as part of a semiconductor processing system, such as the exemplary semiconductor processing system 100 of FIG. 1. In such examples, and with reference to FIG. 1 and FIGS. 5-25, the semiconductor processing system 100 includes a transfer chamber (e.g., transfer chamber 500 of FIG. 5) including a housing 202. In such examples an equipment front-end module 110 (EFEM) is connected to a front face 204 of the housing 202 of the transfer chamber (e.g., 500), where the equipment front-end module 110 includes a front-end substrate transfer robot 146. In such examples, the semiconductor processing system 100 includes a back-end transfer module 104 (BETM) connected to a rear face 206 of the housing 202 of the transfer chamber (e.g., 500), where the back-end transfer module 104 couples one or more process modules (e.g., process module 102) to the transfer chamber (e.g., 500). In such examples, the transfer chamber (e.g., 500 of FIG. 5) includes a first opening 208 through a which a substrate 118 is transferred into and out of a first passage 210 within the housing 202. The transfer chamber (e.g., transfer chamber 500) includes a first gate valve 212 disposed on the front face 204 of the housing 202. In such examples, the first gate valve 212 is either set to an open position to allow transfer of a substrate into the first passage 210 or set to a closed position to form a vacuum seal over the first opening 208. In such examples, the transfer chamber (e.g., transfer chamber 500) includes one or more gas distributors (e.g., gas distributors 502a, 502b, 502c of FIG. 5) disposed on the housing 202 proximate to the first gate valve 212. In such examples, the one or more gas distributors (e.g., gas distributors 502a, 502b, 502c of FIG. 5) include a plurality of gas directing channels (e.g., gas directing channels 504a of FIG. 5) for directing an inert gas over the first opening 208 of the housing 202 to form a gas curtain over the first opening 208.

In accordance with examples of the disclosure, the semiconductor processing systems of the present disclosure can include two or more transfer chambers of the present disclosure. In such examples, the semiconductor processing system further comprises an additional back-end transfer module including one or more coupled additional process modules. In such examples, an additional transfer chamber (e.g., transfer chambers 500, 700, 900, 1100, 1300, 1500, 1700, 1900, 2100, 2200, 2300, and 2400) can couple the additional back-end transfer module (and its associated additional process modules).

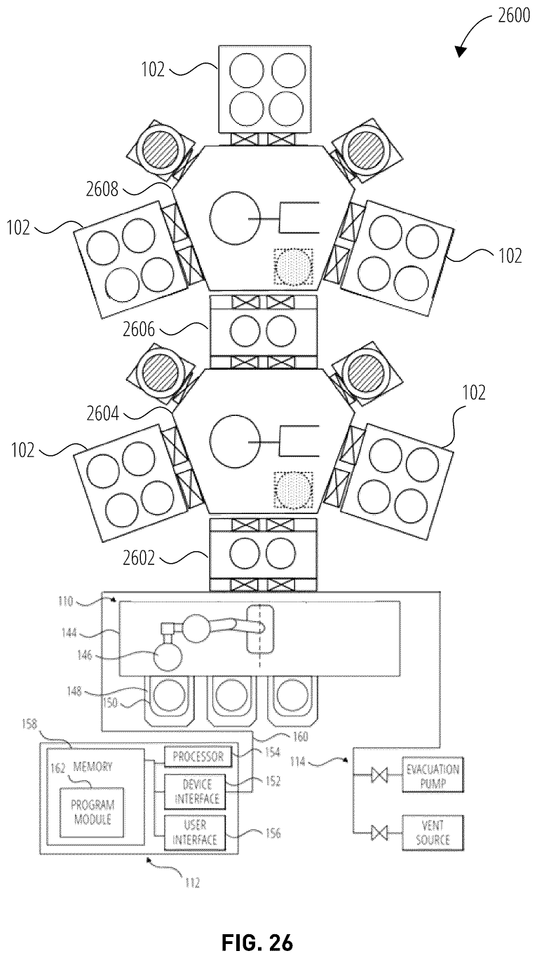

As a non-limiting example, FIG. 26 illustrates a semiconductor processing system 2600 including an equipment front-end module 110 (as described previously) connected to the front face of a first transfer chamber 2602 (e.g., transfer chambers 500, 700, 900, 1100, 1300, 1500, 1700, 1900, 2100, 2200, 2300, and 2400). The rear face of the first transfer chamber 2602 is connected to a first back-end transfer module 2604 which includes various process modules 102. The front face of a second transfer chamber 2606 (e.g., transfer chambers 500, 700, 900, 1100, 1300, 1500, 1700, 1900, 2100, 2200, 2300, and 2400) is connected to the rear of the first back-end transfer module 2604, and the rear face of the second transfer chamber 2606 is connected to a second back-end transfer module 2608 which includes various process modules 102.

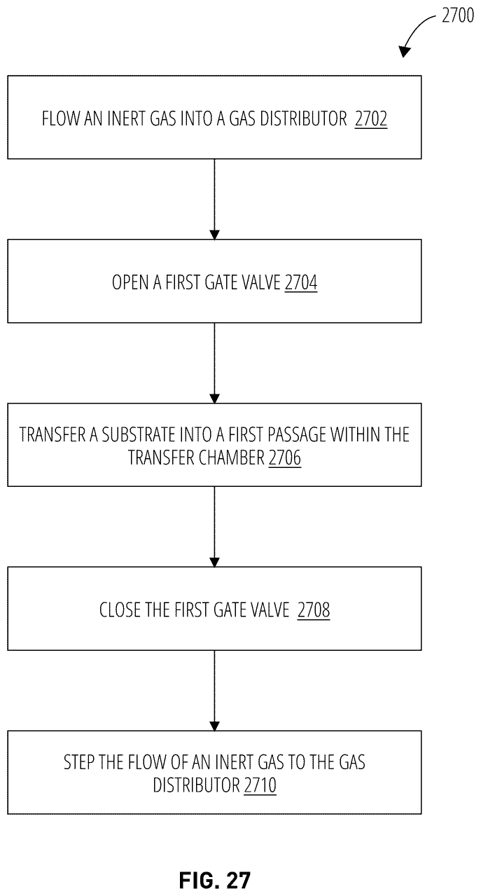

The various embodiments of the present disclosure also provide methods for preventing moisture from entering a transfer chamber. FIG. 27 illustrates an exemplary method 2700 for preventing moisture from entering a transfer chamber.

In accordance with examples of the disclosure, method 2700 includes a step 2702 comprising, flowing an inert gas into one or more gas distributors disposed on a housing of a transfer chamber. In such examples the one or more gas distributors are positioned proximate to a first gate valve. Further in such examples the one or more gas distributors include a plurality of gas directing channels for directing the inert gas over a first opening of the housing to form a gas curtain over the first opening.

In accordance with examples of the disclosure, method 2700 includes a step 2704 comprising opening the first gate valve disposed on a front face of the housing of the transfer chamber.

In accordance with examples of the disclosure, method 2700 includes a step 2706 comprising transferring a substrate into a first passage within the transfer chamber and seating the substrate on a substrate support disposed within the first passage.

In accordance with examples of the disclosure, method 2700 includes a step 2708 comprising closing the first gate valve disposed on the front face of the housing of the transfer chamber.

In accordance with examples of the disclosure, method 2700 also includes a step 2710 comprising stopping the flow of the inert gas into the one or more gas distributors disposed on the housing of the transfer chamber thereby shutting off the gas curtain.

The method 2700 of FIG. 27 can be extending to dual chambers including two passages (and associated components), and quad chambers including four passages (associated components).

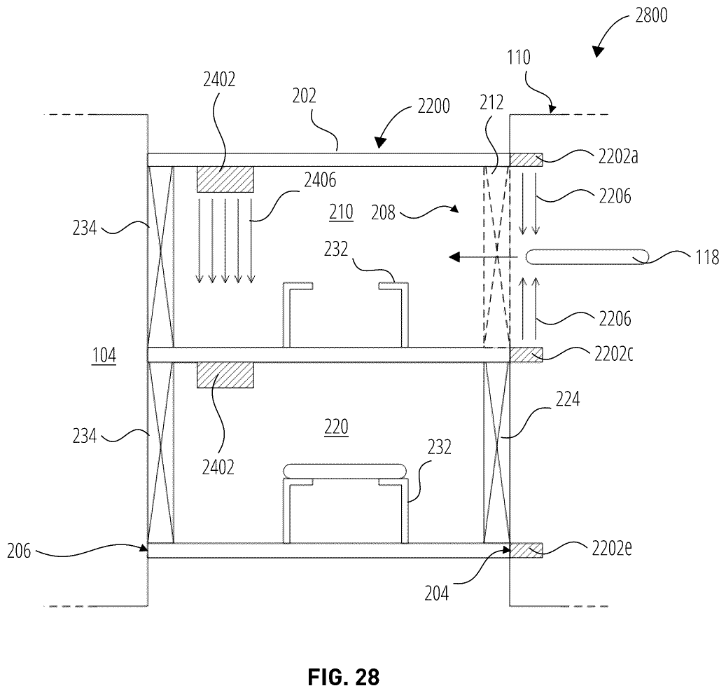

FIG. 28 illustrates the methods of the present disclosure in more detail. FIG. 28 illustrates a cut-away sideview of a portion of a semiconductor processing system 2800 including an equipment front-end module 110, a transfer chamber of the present disclosure (in this case exemplary transfer chamber 2200 as described above), and a back-end transfer module 104. The equipment front-end module 110 is connected to the front face 204 of the transfer chamber 2200 with gas distributors 2202a, 2202c, and 2202e positioned between the transfer chamber 2400 and the equipment front-end module 110. Prior to opening the first gate valve 212, a flow of an inert gas is provided to the gas distributors (e.g., 2202a and 2202c) disposed on the housing 202 of the transfer chamber 2200, where the gas distributors (e.g., 2202a and 2202c) are positioned proximate to a first gate valve 212, and the gas distributors (e.g., 2202a and 2202c) include a plurality of gas directing channels (not shown) for directing the inert gas (gas flow 2206) over a first opening 208 of the housing 202 to form a gas curtain (gas flows 2206) over the first opening 208. Having activated the gas curtain (inert flows 2206) over the first opening, the first gate valve 212 can be opened (as indicated by the dashed lines of the first gate valve 212 in FIG. 28). In such examples, inert gas flow 2206 and the resulting gas curtain prevents moisture from within the equipment front-end module 110 from entering transfer chamber 2400. After opening the first gate valve 212, with the gas curtain in place, a substrate 118 can be transferred into the first passage 210 within the transfer chamber 2400 and subsequently the substrate 118 can be seated on the substrate support 232 disposed within the first passage 210. Once the substrate 118 is seated within the transfer chamber 2400, the first gate valve disposed on the front face of the housing 202 can be closed. After closing the first gate valve 212, the flow of inert gas to the gas distributors (e.g., 2202a, 2202c, and 2202e) can be stopped thereby shutting off the gas curtain over the first gate valve 212. In accordance with examples of the disclosure, this process can be repeated for transferring a subsequent substrate into the one or more passages disposed with the transfer chamber 2400, such as the third passage 222.

In some embodiments, the transfer chamber 2400 can also include the gas diffuser 2402 (as described with reference to FIG. 24). In such embodiments, a flow of inert gas is provided to the gas diffuser 2402 prior to opening the first gate valve 212 and the flow of inert gas provided to the gas diffuser 2402 can be terminated once the substrate 118 is seated on the substrate support 232 and the first gate valve has been returned to the closed position.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A transfer chamber comprising:
a housing including a first opening through which a substrate is transferred into and out of a first passage within the housing;
a first gate valve disposed on a front face of the housing, wherein the first gate valve is either set to an open position to allow the transfer of the substrate into the first passage through the first opening or is set to a closed position to form a vacuum seal over the first opening; and
one or more gas distributors disposed on the housing proximate to the first gate valve, the one or more gas distributors including a plurality of gas directing channels for directing an inert gas over the first opening of the housing to form a gas curtain over the first opening.

2. The transfer chamber of claim 1, wherein the one or more gas distributors are disposed within the housing.

3. The transfer chamber of claim 1, wherein the one or more gas distributors are disposed on an external face of the housing.

4. The transfer chamber of claim 1, wherein the one or more gas distributors are positioned above and/or below the first opening and the gas directing channels extend in a vertical direction for directing the inert gas across a width of the first opening.

5. The transfer chamber of claim 1, wherein the one or more gas distributors are positioned on a side of the first opening and the gas directing channels extend in a horizontal direction for directing the inert gas across a height of the first opening.

6. The transfer chamber of claim 1, wherein the housing further comprising a second opening disposed to a side of the first opening and a second gate valve disposed on the front face of the housing, wherein the second gate valve is either set to the open position to allow passage of the substrate into a second passage through the second opening or is set to the closed position to form a vacuum seal over the second opening.

7. The transfer chamber of claim 6, wherein the one or more gas distributors are positioned above the first opening and the second opening and/or below the first opening and the second opening, and the gas directing channels extend in a vertical direction for directing the inert gas across a width of the first opening and a width of the second opening.

8. The transfer chamber of claim 6, further comprising a second gas distributor positioned above and/or below the second opening, the second gas distributor including second gas directing channels extending in a vertical direction for directing the inert gas across a width of the second opening.

9. The transfer chamber of claim 6, wherein the one or more gas distributors are positioned between the first opening and the second opening and the gas distributors includes first horizontal gas directing channels and second horizontal gas directing channels, the first horizontal gas directing channels extending in a first horizontal direction for directing the inert gas across a height of the first opening and the second horizontal gas directing channels extending in a second horizontal direction for directing the inert gas across a height of the second opening, wherein the first horizontal gas directing channels and the second horizontal gas directing channels are constructed and arranged for directing the inert gas in opposing directions.

10. The transfer chamber of claim 6, wherein the housing further comprising:
a third opening disposed below the first opening and a third gate valve disposed on the front face of the housing, wherein the third gate valve is either set to the open position to allow the transfer of the substrate into a third passage through the third opening or is set the closed position to form a vacuum seal over the third opening; and
a fourth opening disposed below the second opening and to a side of the third opening, and a fourth gate valve disposed on the front face of the housing, wherein the fourth gate valve is either set to the open position to allow passage of the substrate into a fourth passage through the fourth opening or is set the closed position to form a vacuum seal over the fourth opening.

11. The transfer chamber of claim 10, wherein the one or more gas distributors are positioned to a side of the first opening and the third opening and the gas directing channels extend in a horizontal direction for directing the inert gas across a height of the first opening and a height of the third opening.

12. The transfer chamber of claim 10, further comprising a third gas distributor positioned to a side of the third opening, the third gas distributor including third gas directing channels extending in a horizontal direction for directing the inert gas across a height of the third opening.

13. The transfer chamber of claim 10, wherein the one or more gas distributors are positioned between the first opening and the third opening and the gas distributors includes first vertical gas directing channels and second vertical gas directing channels, the first vertical gas directing channels extending in a vertical direction for directing the inert gas across a width of the first opening and the second vertical gas directing channels extending in a vertical direction for directing the inert gas across a width of the third opening, wherein the first vertical gas directing channel and the second vertical gas directing channels are constructed and arranged for directing the inert gas in opposing directions.

14. The transfer chamber of claim 10, wherein the one or more gas distributors are disposed to a side of the first opening and the third opening and/or to a side of the second opening and the fourth opening.

15. The transfer chamber of claim 10, wherein one or more additional gas distributors are disposed above the first opening and the second opening, and/or below the first opening and the second opening, and/or below the third opening and the fourth opening.

16. The transfer chamber of claim 1, further comprising a gas diffuser disposed within the first passage of the housing, the gas diffuser configured distributing a second inert gas into the first passage of the housing.

17. A semiconductor processing system comprising:
a transfer chamber according to claim 1;
an equipment front-end module (EFEM) connected to a front face of a housing of the transfer chamber, the equipment front-end module housing a front-end substrate transfer robot;
a back-end transfer module (BETM) connected to a rear face of the housing of the transfer chamber, the back-end transfer module coupling a process module to the transfer chamber; and
a controller configured to initiate a flow of an inert gas into one or more gas distributors disposed on the front face of the transfer chamber prior to transferring a substrate into the transfer chamber thereby forming a gas curtain between the transfer chamber and the equipment front-end module.

18. The semiconductor processing system of claim 17, further comprising an additional back-end transfer module including one or more additional process modules, and an additional transfer chamber, the additional transfer chamber coupling the additional back-end transfer module to the equipment front-end module.

19. A method of preventing moisture from entering a transfer chamber, the method comprising:
flowing an inert gas into one or more gas distributors disposed on a housing of the transfer chamber, wherein the one or more gas distributors are positioned proximate to a first gate valve, and the one or more gas distributors include a plurality of gas directing channels for directing the inert gas over a first opening of the housing to form a gas curtain over the first opening;
opening the first gate valve disposed on a front face of the housing of the transfer chamber;
transferring a substrate into a first passage within the transfer chamber and seating the substrate on a substrate support disposed within the first passage;
closing the first gate valve disposed on the front face of the housing of the transfer chamber; and
stopping the flow of the inert gas into the one or more gas distributors disposed on the housing of the transfer chamber thereby shutting off the gas curtain.

20. The method of claim 19, further comprising flowing a second inert gas into a gas diffuser disposed within the housing of the transfer chamber prior to opening the first gate valve.
